(19) United States
(12) Patent Application Publication
(10) Pub. No.: US 2020/0035516 A1
(43) Pub. Date: Jan. 30, 2020

(54) SUBSTRATE PROCESSING APPARATUS AND SUBSTRATE PROCESSING METHOD

(71) Applicant: Tokyo Electron Limited, Tokyo (JP)

(72) Inventors: Boui Ikeda, Koshi City (JP); Shoichiro Hidaka, Koshi City (JP)

(21) Appl. No.: 16/520,708

(22) Filed: Jul. 24, 2019

(30) Foreign Application Priority Data
Jul. 25, 2018 (JP) 2018-139746

(51) Int. Cl. H01L 21/67; H01L 21/02; H05B 1/02; H01L 21/687

(52) U.S. Cl. CPC H01L 21/67051; H01L 21/02057; H05B 1/0233; H01L 21/67034; H01L 21/68764; H05B 1/0244

(57) ABSTRACT

A substrate processing apparatus includes a substrate holder configured to hold a substrate on which an irregularity pattern is formed; a liquid supply unit configured to supply a processing liquid onto the substrate from above to thereby form a liquid film which covers a recess of the irregularity pattern; a heating unit comprising a heater and a heating position mover configured to move a heating position heated by the heater; and a heating controller. While overlapping the heating position with a boundary portion when viewed from a vertical direction, the boundary portion being provided between an exposed portion where the recess is entirely exposed and a covered portion where the recess is entirely filled with the processing liquid in a depth direction thereof, the heating controller moves the heating position in a moving direction of the boundary portion as a direction in which the exposed portion is enlarged.

### CROSS-REFERENCE TO RELATED APPLICATION

This application claims the benefit of Japanese Patent Application No. 2018-139746 filed on Jul. 25, 2018, the entire disclosures of which are incorporated herein by reference.

### TECHNICAL FIELD

The various aspects and embodiments described herein pertain generally to a substrate processing apparatus and a substrate processing method.

### BACKGROUND

A liquid processing system described in Patent Document 1 includes a liquid processing apparatus configured to perform a liquid processing by supplying a processing liquid onto a substrate; and a controller configured to control the liquid processing apparatus. The liquid processing apparatus is equipped with a substrate holder configured to hold a substrate, a first supply configured to supply a volatile fluid onto a front surface of the substrate held by the substrate holder; and a second supply configured to supply a heating fluid to a rear surface of the substrate held by the substrate holder. As an example of the volatile fluid, IPA (isopropyl alcohol) may be used. The IPA is supplied onto a pattern formation surface of the substrate. As an example of the heating fluid, heated pure water may be used. The controller controls the liquid processing apparatus to perform a volatile fluid supplying processing, an exposing processing and a heated fluid supplying processing. The volatile fluid supplying processing is a processing of forming a liquid film on the front surface of the substrate by supplying the volatile fluid onto the front surface of the substrate from the first supply. The exposing processing is a processing of exposing the front surface of the substrate from the volatile fluid. The heated fluid supplying processing, which is begun prior to the exposing processing, is a processing of supplying the heated fluid to the rear surface of the substrate from the second supply in a period which overlaps with a period of the exposing processing.

Patent Document 1: Japanese Patent Laid-open Publication No. 2014-090015

### SUMMARY

In one exemplary embodiment, a substrate processing apparatus includes a substrate holder configured to hold a substrate such that a surface of the substrate on which an irregularity pattern is formed faces upwards; a liquid supply unit configured to supply a processing liquid onto the substrate, which is held by the substrate holder, from above the substrate to thereby form a liquid film which covers a recess of the irregularity pattern; a heating unit comprising a heater configured to locally heat the liquid film and a heating position mover configured to move a heating position heated by the heater; and a heating controller configured to control the heating unit. While overlapping the heating position with a boundary portion when viewed from a vertical direction, the boundary portion being provided between an exposed portion where the recess is entirely exposed from the processing liquid in a depth direction thereof and a covered portion where the recess is entirely filled with the processing liquid in the depth direction thereof, the heating controller moves the heating position in a moving direction of the boundary portion as a direction in which the exposed portion is enlarged.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a substrate processing apparatus according to a first exemplary embodiment;

FIG. 2 is a functional block diagram illustrating constituent components of a controller according to the first exemplary embodiment;

FIG. 3 is a flowchart illustrating a substrate processing method according to the first exemplary embodiment;

FIG. 4A to FIG. 4D are diagrams illustrating parts of a substrate processing according to the first exemplary embodiment;

FIG. 5A to FIG. 5D are diagrams illustrating another part of the substrate processing according to the first exemplary embodiment;

FIG. 6 provides an enlarged view of a part of FIG. 5B to illustrate a boundary portion between an exposed portion and a covered portion according the first exemplary embodiment;

FIG. 7 is a timing chart showing operations of a rotation driver, a drying liquid discharge nozzle, a heating liquid discharge nozzle, a vertical nozzle and an inclined nozzle according to the first exemplary embodiment;

FIG. 8 is a diagram showing a relationship between an arrival position of the boundary portion and a substrate temperature at the boundary portion according to the first exemplary embodiment;

FIG. 9A and FIG. 9B are diagrams illustrating parts of a substrate processing according to a second exemplary embodiment;

FIG. 10 is a timing chart showing operations of a rotation driver, a drying liquid discharge nozzle, a heating liquid discharge nozzle, a vertical nozzle and an inclined nozzle according to the second exemplary embodiment;

FIG. 11A to FIG. 11D are diagrams illustrating a part of a substrate processing according to a third exemplary embodiment;

FIG. 12 is a timing chart showing operations of a rotation driver, a drying liquid discharge nozzle, a heating liquid discharge nozzle, a vertical nozzle and an inclined nozzle according to the third exemplary embodiment;

FIG. 13 is a diagram illustrating a substrate holder and a heating unit according to a fourth exemplary embodiment;

FIG. 14 provides a perspective view corresponding to FIG. 15B to illustrate a part of a substrate processing according to a fifth exemplary embodiment; and

FIG. 15A to FIG. 15C are side views illustrating parts of the substrate processing according to the fifth exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments will be described with reference to the accompanying drawings. In the various drawings, same or corresponding parts will be assigned same or corresponding reference numerals, and redundant description may be omitted. In the present specification, “downwards” means vertically downwards, and “upwards” means vertically upwards.

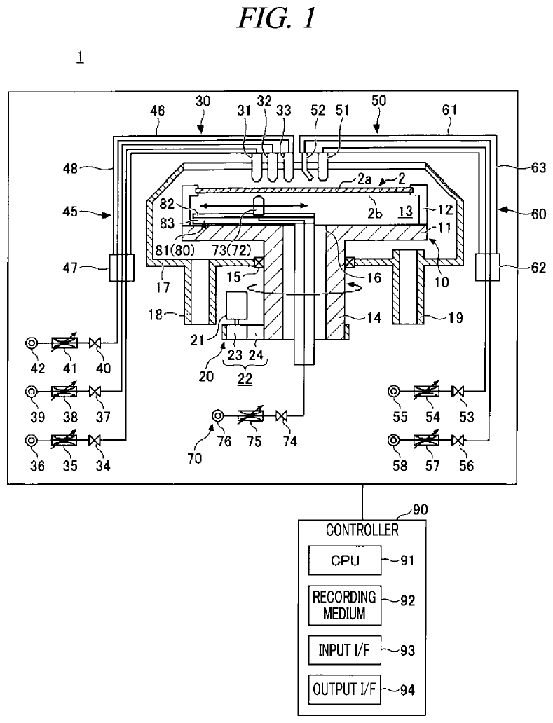

FIG. 1 is a diagram illustrating a substrate processing apparatus according to a first exemplary embodiment. As depicted in FIG. 1, a substrate processing apparatus 1 includes, by way of example, a substrate holder 10, a rotation driver 20, a liquid supply unit 30, a gas supply unit 50, a heating unit 70 and a controller 90.

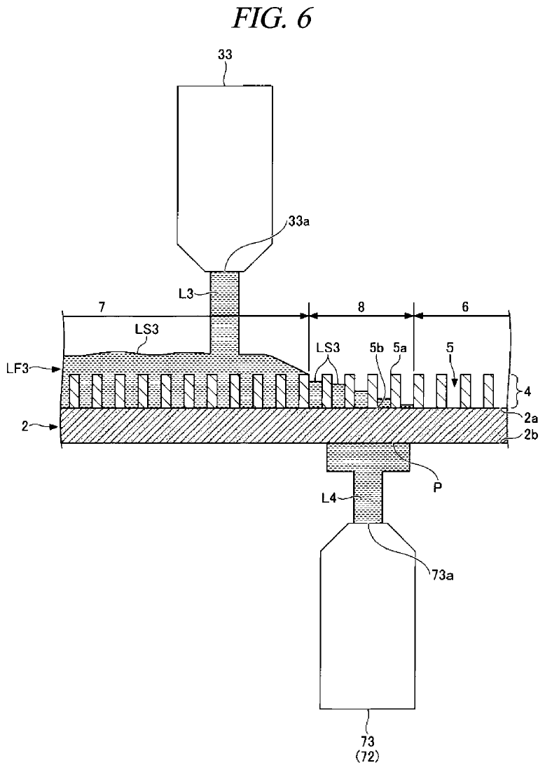

The substrate holder 10 is configured to hold a substrate 2 horizontally with a top surface 2a of the substrate 2, where an irregularity pattern 4 (see FIG. 6) is formed, facing upwards. The substrate 2 is a semiconductor substrate such as, but not limited to, a silicon wafer. The irregularity pattern 4 is formed by, for example, a photolithography method. Besides the photolithography method, an etching method may be performed. For example, the irregularity pattern 4 is formed by etching a film (for example, a silicon nitride film) formed on the substrate 2. The irregularity pattern 4 has a recess 5 which is opened upwards.

The substrate holder 10 is equipped with a disk-shaped plate 11 and claws 12 provided at an outer periphery portion of the plate 11. The claws 12 are arranged at a regular interval along the circumference of the plate 11. The claws 12 are configured to hold an edge of the substrate 2 while allowing the substrate 2 to be spaced apart from the plate 11. A clearance space 13 is provided between the substrate 2 and the plate 11.

Further, the substrate holder 10 is equipped with a rotation shaft 14 extending downwards from a center of the plate 11. The rotation shaft 14 is rotatably supported by a shaft bearing 15. A through hole 16 is formed at the center of the plate 11, and the rotation shaft 14 has a cylindrical shape. An internal space of the rotation shaft 14 communicates with the clearance space 13 through the through hole 16.

The rotation driver 20 is configured to rotate the substrate holder 10. The rotation driver 20 rotates the substrate holder 10 around the rotation shaft 14 of the substrate holder 10. Along with the rotation of the substrate holder 10, the substrate 2 held by the substrate holder 10 is also rotated.

The rotation driver 20 is equipped with a rotation motor 21 and a transmission mechanism 22 configured to transfer a rotational motion of the rotation motor 21 to the rotation shaft 14. The transmission mechanism 22 includes, by way of example, a pulley 23 and a timing belt 24. The pulley 23 is mounted to an output shaft of the rotation motor 21 and is rotated along with the output shaft. The timing belt 24 is wound around the pulley 23 and the rotation shaft 14. The transmission mechanism 22 transfers the rotational motion of the rotation motor 21 to the rotation shaft 14. Further, the transmission mechanism 22 may include a plurality of gears instead of the pulley 23 and the timing belt 24.

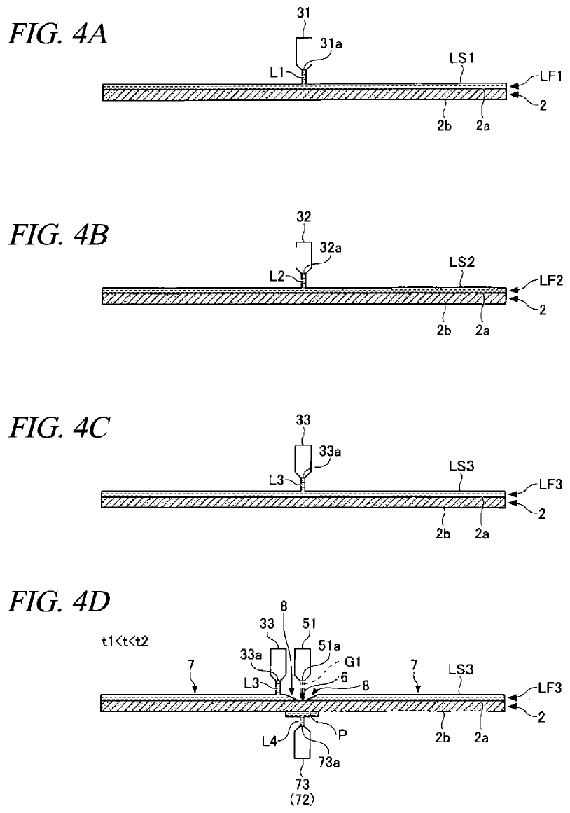

The liquid supply unit 30 is configured to supply a processing liquid onto the substrate 2 held by the substrate holder 10 from above the substrate 2. The liquid supply unit 30 may supply multiple kinds of processing liquids and may supply the processing liquids depending on a processing stage of the substrate 2. The processing liquids supplied by the liquid supply unit 30 may include, by way of example, but not limitation, a cleaning liquid L1 (see FIG. 4A), a rinse liquid L2 (see FIG. 4B) and a drying liquid L3 (see FIG. 4C). The cleaning liquid may sometimes be referred to as a chemical liquid.

The liquid supply unit 30 is equipped with liquid discharge nozzles configured to discharge the processing liquids. The liquid discharge nozzles of the liquid supply unit 30 may include, by way of example, a cleaning liquid discharge nozzle 31, a rinse liquid discharge nozzle 32 and a drying liquid discharge nozzle 33. The cleaning liquid discharge nozzle 31 discharges the cleaning liquid L1; the rinse liquid discharge nozzle 32, the rinse liquid L2; and the drying liquid discharge nozzle 33, the drying liquid L3. Further, a single liquid discharge nozzle may discharge the multiple kinds of processing liquids. Furthermore, the liquid discharge nozzle may discharge a processing liquid mixed with a gas.

The cleaning liquid discharge nozzle 31 is connected to a supply source 36 via an opening/closing valve 34 and a flow rate control valve 35. If the opening/closing valve 34 opens a flow path for the cleaning liquid L1, the cleaning liquid L1 is discharged from the cleaning liquid discharge nozzle 31. Meanwhile, if the opening/closing valve 34 closes the flow path for the cleaning liquid L1, the discharge of the cleaning liquid L1 from the cleaning liquid discharge nozzle 31 is stopped. The flow rate control valve 35 adjusts a flow rate of the cleaning liquid L1 which is discharged from the cleaning liquid discharge nozzle 31. The supply source 36 supplies the cleaning liquid L1 to the cleaning liquid discharge nozzle 31.

Though not particularly limited, the cleaning liquid L1 may be, by way of example, DHF (Dilute Hydrofluoric Acid). The cleaning liquid L1 may have a room temperature, or a temperature higher than the room temperature and lower than a boiling point of the cleaning liquid L1.

Here, the cleaning liquid L1 is not limited to the DHF, and any of various general liquids for used in cleaning a semiconductor substrate may be used. By way of non-limiting example, the cleaning liquid L1 may be SC-1 (an aqueous solution containing ammonium hydroxide and hydrogen peroxide) or SC-2 (an aqueous solution containing hydrogen chloride and hydrogen peroxide). Further, multiple kinds of cleaning liquid L1 may be used.

The rinse liquid discharge nozzle 32 is connected to a supply source 39 via an opening/closing valve 37 and a flow rate control valve 38. If the opening/closing valve 37 opens a flow path for the rinse liquid L2, the rinse liquid L2 is discharged from the rinse liquid discharge nozzle 32. Meanwhile, if the opening/closing valve 37 closes the flow path for the rinse liquid L2, the discharge of the rinse liquid L2 from the rinse liquid discharge nozzle 32 is stopped. The flow rate control valve 38 adjusts a flow rate of the rinse liquid L2 which is discharged from the rinse liquid discharge nozzle 32. The supply source 39 supplies the rinse liquid L2 to the rinse liquid discharge nozzle 32.

Though not particularly limited, the rinse liquid L2 may be, by way of example, DIW (Deionized Water). The rinse liquid L2 may have a room temperature, or a temperature higher than the room temperature and lower than a boiling point of the rinse liquid L2. The higher the temperature of the rinse liquid L2 is, the lower a surface tension of the rinse liquid L2 may be.

The drying liquid discharge nozzle 33 is connected to a supply source 42 via an opening/closing valve 40 and a flow rate control valve 41. If the opening/closing valve 40 opens a flow path for the drying liquid L3, the drying liquid L3 is discharged from the drying liquid discharge nozzle 33. Meanwhile, if the opening/closing valve 40 closes the flow path for the drying liquid L3, the discharge of the drying liquid L3 from the drying liquid discharge nozzle 33 is stopped. The flow rate control valve 41 adjusts a flow rate of the drying liquid L3 which is discharged from the drying liquid discharge nozzle 33. The supply source 42 supplies the drying liquid L3 to the drying liquid discharge nozzle 33.

Though not particularly limited, the drying liquid L3 may be, by way of example, IPA (Isopropyl Alcohol). The IPA has a surface tension lower than that of the DIW. The drying liquid L3 may have a room temperature, or a temperature higher than the room temperature and lower than a boiling point of the drying liquid L3. The higher the temperature of the drying liquid L3 is, the lower a surface tension of the drying liquid L3 may be.

Furthermore, the drying liquid L3 is not limited to the IPA as long as it has a surface tension lower than that of the rinse liquid L2. By way of non-limiting example, the drying liquid L3 may be HFE (Hydro Fluoro Ether), methanol, ethanol, acetone, or trans-1,2-dichloroethylene.

The liquid supply unit 30 supplies the processing liquid such as the cleaning liquid L1, the rinse liquid L2 or the drying liquid L3 onto a central portion of the substrate 2 being rotated along with the substrate holder 10. The processing liquid supplied to the central portion of the substrate 2 being rotated is diffused onto the entire top surface 2a of the substrate 2 to be scattered from the edge of the substrate 2 by a centrifugal force. Liquid droplets of the scattered processing liquid are received by a cup 17.

The cup 17 holds the shaft bearing 15 which supports the substrate holder 10 in a rotatable manner, and is not rotated along with the substrate holder 10. A liquid drain pipe 18 and a gas exhaust pipe 19 are provided at a bottom of the cup 17. A liquid within the cup 17 is drained through the liquid drain pipe 18, and a gas within the cup 17 is exhausted through the gas exhaust pipe 19.

The liquid supply unit 30 is equipped with a liquid discharge nozzle moving mechanism 45. The liquid discharge nozzle moving mechanism 45 is configured to move the cleaning liquid discharge nozzle 31, the rinse liquid discharge nozzle 32 and the drying liquid discharge nozzle 33 in the horizontal direction. The liquid discharge nozzle moving mechanism 45 moves the cleaning liquid discharge nozzle 31, the rinse liquid discharge nozzle 32 and the drying liquid discharge nozzle 33 between a position directly above the central portion of the substrate 2 and a position directly above an edge portion of the substrate 2. Further, the cleaning liquid discharge nozzle 31, the rinse liquid discharge nozzle 32 and the drying liquid discharge nozzle 33 may be further moved to a standby position which is located outer than the edge portion of the substrate 2 in a diametrical direction of the substrate 2.

For example, the liquid discharge nozzle moving mechanism 45 is equipped with a revolving arm 46 and a revolving mechanism 47 configured to revolve the revolving arm 46. The revolving arm 46 is disposed horizontally, and holds the cleaning liquid discharge nozzle 31, the rinse liquid discharge nozzle 32 and the drying liquid discharge nozzle 33 at a leading end thereof with their discharge openings 31a, 32a and 33a (see FIG. 4A to FIG. 4D) facing downwards. The revolving mechanism 47 revolves the revolving arm 46 around a revolving shaft 48 extending downwards from a base end of the revolving arm 46. By revolving the revolving arm 46, the liquid discharge nozzle moving mechanism 45 moves the cleaning liquid discharge nozzle 31, the rinse liquid discharge nozzle 32 and the drying liquid discharge nozzle 33 in the horizontal direction.

Further, the liquid discharge nozzle moving mechanism 45 may have a guide rail and a linearly moving mechanism instead of the revolving arm 46 and the revolving mechanism 47. The guide rail is disposed horizontally, and the linearly moving mechanism moves the cleaning liquid discharge nozzle 31, the rinse liquid discharge nozzle 32 and the drying liquid discharge nozzle 33 along the guide rail. Further, though the liquid discharge nozzle moving mechanism 45 moves the cleaning liquid discharge nozzle 31, the rinse liquid discharge nozzle 32 and the drying liquid discharge nozzle 33 at the same time at the same rate in the same direction in the present exemplary embodiment, the nozzles may be moved separately.

The gas supply unit 50 supplies a gas onto the substrate 2 held by the substrate holder 10 from above. The gas supplied onto the substrate 2 presses a liquid film formed on the substrate 2 to press a boundary portion 8 between an exposed portion 6 and a covered portion 7 shown in FIG. 6.

The exposed portion 6 is a portion of the irregularity pattern 4 where a recess 5 is entirely exposed from the drying liquid L3 in the depth direction thereof. Since the drying liquid L3 does not exist at the exposed portion 6, the surface tension of the drying liquid L3 does not act on the exposed portion 6.

The covered portion 7 is a portion of the irregularity pattern 4 where the recess 5 is entirely filled with the drying liquid L3 in the depth direction thereof. At the covered portion 7, a height of a liquid surface LS3 of the drying liquid L3 is higher than an upper end 5a of the recess 5. Thus, the surface tension of the drying liquid L3 does not act on the covered portion 7.

The boundary portion 8 is a portion of the irregularity pattern 4 where only a part of the recess 5 in the depth direction thereof is in contact with the drying liquid L3. At the boundary portion 8, the height of the liquid surface LS3 of the drying liquid L3 is lower than the height of the upper end 5a of the recess 5 and higher than a lower end 5b of the recess 5. Since a sidewall surface of the recess 5 at the boundary portion 8 is in contact with the liquid surface LS3, the surface tension of the drying liquid L3 acts on the boundary portion 8.

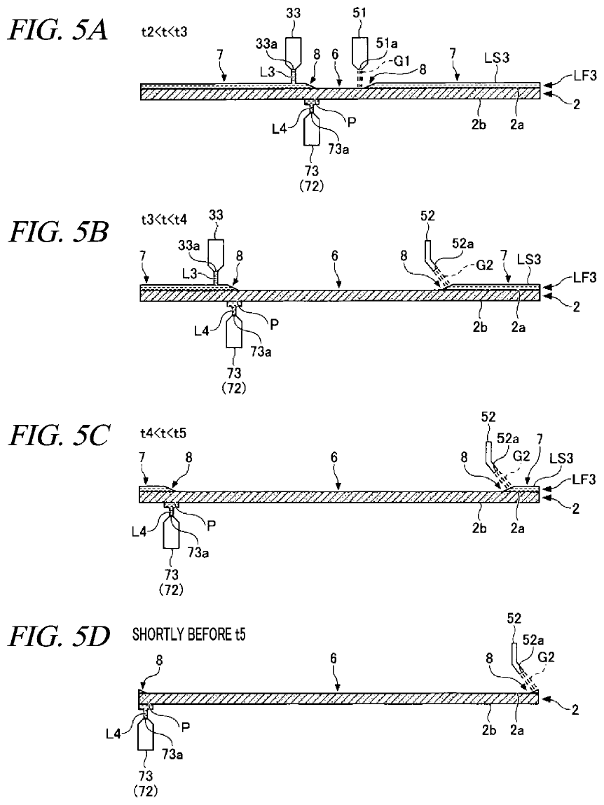

The gas supply unit 50 has gas discharge nozzles configured to discharge gases. The gas supply unit 50 has, by way of example, a vertical nozzle 51 and an inclined nozzle 52 as the gas discharge nozzles. The vertical nozzle 51 discharges a gas G1 in the vertical direction (see FIG. 4A to FIG. 4D). The inclined nozzle 52 discharges a gas G2 in an inclined manner with respect to the vertical direction (see FIG. 5A to FIG. 5D).

The vertical nozzle 51 is connected to a supply source 55 via an opening/closing valve 53 and a flow rate control valve 54. If the opening/closing valve 53 opens a flow path for the gas G1, the gas G1 is discharged from the vertical nozzle 51. Meanwhile, if the opening/closing valve 53 closes the flow path for the gas G1, the discharge of the gas G1 from the vertical nozzle 51 is stopped. The flow rate control valve 54 adjusts a flow rate of the gas G1 discharged from the vertical nozzle 51. The supply source 55 supplies the gas G1 into the vertical nozzle 51.

The gas G1 is not particularly limited, and, by way of example, a nitrogen gas, a dry air or the like may be used. The gas G1 may have a room temperature or a temperature higher than the room temperature. If the gas G1 has the temperature higher than the room temperature, the temperature of the gas G1 may be lower than the boiling point of the drying liquid L3.

The inclined nozzle 52 is connected to a supply source 58 via an opening/closing valve 56 and a flow rate control valve 57. If the opening/closing valve 56 opens a flow path for the gas G2, the gas G2 is discharged from the inclined nozzle 52. Meanwhile, if the opening/closing valve 56 closes the flow path for the gas G2, the discharge of the gas G2 from the inclined nozzle 52 is stopped. The flow rate control valve 57 adjusts a flow rate of the gas G2 discharged from the inclined nozzle 52. The supply source 58 supplies the gas G2 into the inclined nozzle 52.

Though not particularly limited, the gas G2 may be, by way of non-limiting example, a nitrogen gas, a dry air or the like. The gas G2 may have a room temperature or a temperature higher than the room temperature. If the gas G2 has the temperature higher than the room temperature, the temperature of the gas G2 may be lower than the boiling point of the drying liquid L3. In case that the gas G1 and the gas G2 are same, the supply source 55 and the supply source 58 may be configured as a single body.

The gas supply unit 50 is equipped with a gas discharge nozzle moving mechanism 60. The gas discharge nozzle moving mechanism 60 is configured to move the vertical nozzle 51 and the inclined nozzle 52 in the horizontal direction. The gas discharge nozzle moving mechanism 60 moves the vertical nozzle 51 and the inclined nozzle 52 between a position directly above a central portion of the substrate 2 and a position directly above an edge portion of the substrate 2. Further, the vertical nozzle 51 and the inclined nozzle 52 may be further moved to a standby position outer than the edge portion of the substrate 2 in a diametrical direction of the substrate 2.

By way of example, the gas discharge nozzle moving mechanism 60 has a revolving arm 61 and a revolving mechanism 62 configured to revolve the revolving arm 61. The revolving arm 61 is disposed horizontally, and holds the vertical nozzle 51 and the inclined nozzle 52 at a leading end thereof with their discharge openings 51a and 52a (see FIG. 5A to FIG. 5D) facing downwards. The revolving mechanism 62 revolves the revolving arm 61 around a revolving shaft 63 extending downwards from a base end of the revolving arm 61. By revolving the revolving arm 61, the gas discharge nozzle moving mechanism 60 moves the vertical nozzle 51 and the inclined nozzle 52 in the horizontal direction.

Further, the gas discharge nozzle moving mechanism 60 may have a guide rail and a linearly moving mechanism instead of the revolving arm 61 and the revolving mechanism 62. The guide rail is disposed horizontally, and the linearly moving mechanism moves the vertical nozzle 51 and the inclined nozzle 52 along the guide rail. Further, though the gas discharge nozzle moving mechanism 60 moves the vertical nozzle 51 and the inclined nozzle 52 at the same time at the same rate in the same direction in the present exemplary embodiment, the nozzles may be moved separately.

The heating unit 70 is equipped with a heater 72 configured to locally heat a liquid film LF3 of the drying liquid L3. The heater 72 has a heating liquid discharge nozzle 73 configured to discharge a heating liquid L4 (see FIG. 4A to FIG. 6) onto the substrate 2 held by the substrate holder 10 from below.

The heating liquid L4 comes into contact with the substrate 2 to heat the substrate 2. Since the heating liquid L4 is supplied from the opposite side from the drying liquid L3 with respect to the substrate 2, the heating liquid L4 and the drying liquid L3 can be suppressed from being mixed with each other. Since only the drying liquid L3 having the surface tension lower than the heating liquid L4 covers the irregularity pattern 4, the pattern collapse can be suppressed.

The heating liquid discharge nozzle 73 is connected to a supply source 76 via an opening/closing valve 74 and a flow rate control valve 75. If the opening/closing valve 74 opens a flow path for the heating liquid L4, the heating liquid L4 is discharged from the heating liquid discharge nozzle 73. Meanwhile, if the opening/closing valve 74 closes the flow path for the heating liquid L4, the discharge of the heating liquid L4 from the heating liquid discharge nozzle 73 is stopped. The flow rate control valve 75 adjusts a flow rate of the heating liquid L4 discharged from the heating liquid discharge nozzle 73. The supply source 76 supplies the heating liquid L4 into the heating liquid discharge nozzle 73.

Though not particularly limited, the heating liquid L4 may be, by way of example, DIW. Since the DIW has a specific heat higher than that of alcohol such as IPA, a large amount of heat can be stored to be supplied to the substrate 2.

The heating liquid L4 may have a temperature higher than the room temperature and lower than a boiling point of the heating liquid L4. Thus, boiling of the heating liquid L4 can be suppressed and vaporizing of the drying liquid L3 can be accelerated. To suppress the boiling of the drying liquid L3 more securely, the temperature of the heating liquid L4 may be set to be lower than the boiling point of the drying liquid L3.

Further, the temperature of the heating liquid L4 may be set to be higher than the boiling point of the drying liquid L3 as long as the boiling of the drying liquid L3 can be suppressed. The temperature of the drying liquid L3 becomes lower than the temperature of the heating liquid L4 as heat is gradually lost when the heat is transferred from the heating liquid L4 to the drying liquid L3.

A feed flow rate of the heating liquid L4 may be set such that the heating liquid L4 falls into the heating liquid discharge nozzle 73 from the substrate 2 after coming into contact with the substrate 2 or such that the heating liquid L4 flows outwards in the diametrical direction of the substrate 2 toward an outer position than the heating liquid discharge nozzle 73 by a centrifugal force while the heating liquid L4 is kept in contact with the substrate 2. If the heating liquid L4 comes into contact with the substrate 2, the heating liquid L4 is deprived of heat by the substrate 2. Thus, even if the heating liquid L4 flows outwards in the diametrical direction of the substrate 2, the substrate 2 can be heated locally.

Furthermore, to narrow a heating range of the heating liquid L4, the heating unit 70 may have a sucking nozzle configured to suck the heating liquid L4 which has come into contact with the substrate 2. The sucking nozzle is disposed at an outer position than the heating liquid discharge nozzle 73 in the diametrical direction of the substrate 2 and collects the heating liquid L4 flown to the outer position than the heating liquid discharge nozzle 73 in the diametrical direction of the substrate 2.

The heating unit 70 is equipped with a heating position mover 80. The heating position mover 80 moves a heating position P on a heating surface (for example, a bottom surface 2b of the substrate 2) heated by the heater 72 (hereinafter, simply referred to as “heating position P”). As will be elaborated later, the heating position P can be moved in a moving direction of the boundary portion 8 while being overlapped with the boundary portion 8 when viewed from the vertical direction. The moving direction of the boundary portion 8 is a direction in which the exposed portion 6 is enlarged.

For example, the heating position mover 80 moves the heating position P from an inner side of the substrate 2 toward an outer side of the substrate 2 in the diametrical direction. When the rotation driver 20 rotates the substrate holder 10, the boundary portion 8 may be moved from the inner side of the substrate 2 toward the outer side of the substrate 2 in the diametrical direction not to be against the centrifugal force.

The heating position mover 80 includes a heater moving mechanism 81. By moving the heater 72, the heater moving mechanism 81 moves the heating position P. With this configuration, since multiple positions distanced apart in the moving direction of the heating position P can be heated by the single heater 72, the number of the heater 72 required to be provided can be reduced. By way of example, the heater 72 is disposed in the clearance space 13 between the substrate 2 and the plate 11 to be movable between a position directly under the central portion of the substrate 2 and a position directly under the edge portion of the substrate 2.

The heater moving mechanism 81 may have, by way of example, a guide rail 82 and a linearly moving mechanism 83. The guide rail 82 guides the heater 72 in the diametrical direction of the substrate 2. For example, the guide rail 82 is disposed horizontally within the clearance space 13 formed between the substrate 2 and the plate 11. The linearly moving mechanism 83 moves the heater 72 along the guide rail 82. The linearly moving mechanism 83 includes, for example, a rotary motor and a ball screw configured to convert a rotational motion of the rotary motor to a straight line motion of the heater 72.

The controller 90 is composed of, by way of example, a computer, and includes a CPU (Central processing unit) 91 and a recording medium 92 such as a memory. The recording medium 92 stores therein a program for controlling various kinds of processings performed in the substrate processing apparatus 1. The controller 90 controls an operation of the substrate processing apparatus 1 by allowing the CPU 91 to execute the program stored in the recording medium 92. Further, the controller 90 is equipped with an input interface 93 and an output interface 94. The controller 90 receives a signal from the outside through the input interface 93 and transmits a signal to the outside through the output interface 94.

Such a program may be stored in a computer-readable recording medium and installed from this recording medium to the recording medium 92 of the controller 90. The computer-readable recording medium may be, by way of non-limiting example, a hard disk (HD), a flexible disk (FD), a compact disk (CD), a magnet optical disk (MO), a memory card, or the like. Furthermore, the program may be downloaded from a server through Internet and installed in the recording medium 92 of the controller 90.

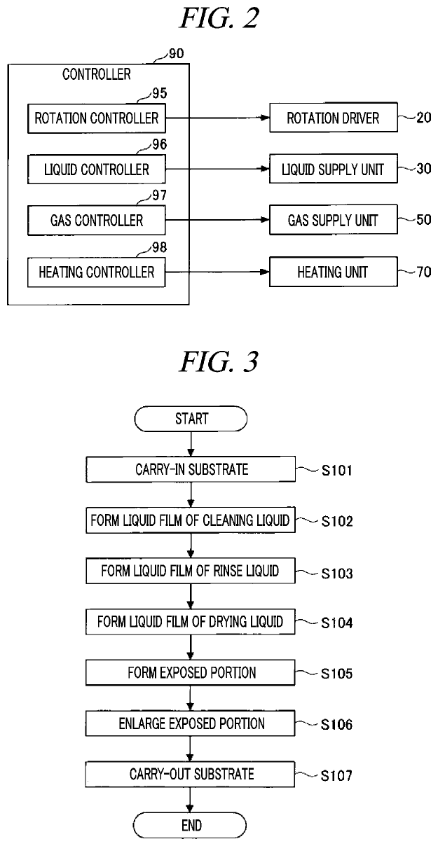

FIG. 2 is a functional block diagram illustrating constituent components of the controller according to the first exemplary embodiment. Each functional block shown in FIG. 2 is conceptual and need not necessarily be physically configured as shown in FIG. 2. All or a part of the functional blocks may be functionally or physically dispersed or combined on a unit. All or a part of processing functions performed in the respective functional blocks may be implemented by a program performed in the CPU or implemented by hardware through a wired logic.

The controller 90 includes a rotation controller 95, a liquid controller 96, a gas controller 97 and a heating controller 98. The rotation controller 95 controls the rotation driver 20. The liquid controller 96 controls the liquid supply unit 30. The gas controller 97 controls the gas supply unit 50. The heating controller 98 controls the heating unit 70. Specific controls will be elaborated later.

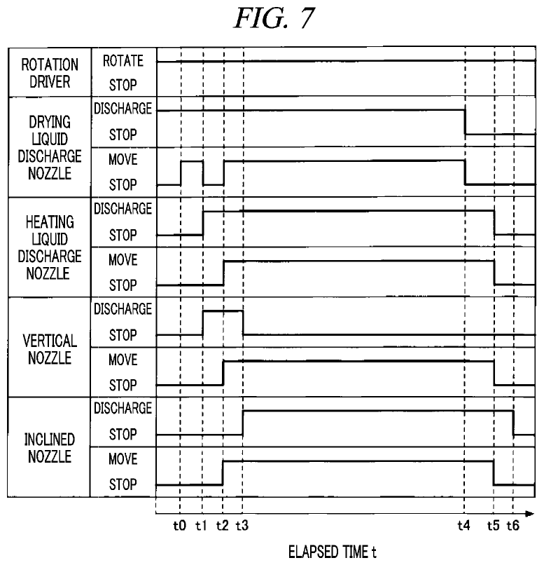

FIG. 3 is a flowchart illustrating a substrate processing method according to the first exemplary embodiment. FIG. 4A to FIG. 4D are diagrams illustrating parts of a substrate processing according to the first exemplary embodiment. FIG. 4A is a diagram showing a state where the liquid film of the cleaning liquid is formed according to the first exemplary embodiment; FIG. 4B, a state where the liquid film of the rinse liquid is formed according to the first exemplary embodiment; FIG. 4C, a state where the liquid film of the drying liquid is formed according to the first exemplary embodiment; and FIG. 4D, a state where the exposed portion is formed at the central portion of the liquid film of the drying liquid according to the first exemplary embodiment. FIG. 5A to FIG. 5D are diagrams illustrating other parts of the substrate processing according to the first exemplary embodiment. FIG. 5A is a diagram showing a state at the beginning of enlargement of the exposed portion according to the first exemplary embodiment; FIG. 5B, a state during the enlargement of the exposed portion according to the first exemplary embodiment; FIG. 5C, a state upon the completion of the discharge of the drying liquid according to the first exemplary embodiment; FIG. 5D, a state shortly before the completion of the enlargement of the exposed portion according to the first exemplary embodiment. FIG. 6 presents an enlarged view of a part of FIG. 5B to illustrate the boundary portion between the exposed portion and the covered portion according to the first exemplary embodiment. FIG. 7 is a timing chart showing operations of the rotation driver, the drying liquid discharge nozzle, the heating liquid discharge nozzle, the vertical nozzle and the inclined nozzle according to the first exemplary embodiment.

The substrate processing method includes a process S101 of carrying the substrate 2 before being processed into the substrate processing apparatus 1 (see FIG. 3). The substrate processing apparatus 1 holds the substrate 2, which has been carried by a non-illustrated transfer device, by the substrate holder 10. The substrate holder 10 holds the substrate 2 horizontally with the irregularity pattern 4 formed on the substrate 2 facing upwards.

The substrate processing method includes a process S102 of supplying the cleaning liquid L1 onto the substrate 2 held by the substrate holder 10 from above to thereby form the liquid film LF1 of the cleaning liquid L1, covering the irregularity pattern 4 (see FIG. 3). In this process S102, the cleaning liquid discharge nozzle 31 is disposed directly above the central portion of the substrate 2 (see FIG. 4A). The cleaning liquid discharge nozzle 31 supplies the cleaning liquid L1 to the central portion of the substrate 2, which is being rotated along with the substrate holder 10, from above. The supplied cleaning liquid L1 is diffused on the entire top surface 2a of the substrate 2 by the centrifugal force, so that the liquid film LF1 is formed. To clean the entire irregularity pattern 4, the rotation number of the substrate holder 10 and the feed flow rate of the cleaning liquid L1 are set such that the height of the liquid film LS1 of the cleaning liquid L1 is higher than the height of the upper end 5a (see FIG. 6) of the recess 5.

The substrate processing method includes a process S103 of replacing the previously formed liquid film LF1 of the cleaning liquid L1 with the liquid film LF2 of the rinse liquid L2 (see FIG. 3). In this process S103, the rinse liquid discharge nozzle 32 is disposed directly above the central portion of the substrate 2 instead of the cleaning liquid discharge nozzle 31 (see FIG. 4B). The discharge of the cleaning liquid L1 from the cleaning liquid discharge nozzle 31 is stopped, whereas the discharge of the rinse liquid L2 from the rinse liquid discharge nozzle 32 is begun. The rinse liquid L2 is supplied onto the central portion of the substrate 2, which is being rotated along with the substrate holder 10, and diffused on the entire top surface 2a of the substrate 2 by the centrifugal force, so that the liquid film LF2 is formed. Accordingly, the cleaning liquid L1 remaining in the irregularity pattern 4 is replaced by the rinse liquid L2. The rotation number of the substrate holder 10 and the feed flow rate of the rinse liquid L2 are set such that the heights of the liquid surfaces LS1 and LS2 are maintained higher than the height of the upper end 5a (see FIG. 6) of the recess 5 during the replacement of the cleaning liquid L1 by the rinse liquid L2. Thus, the pattern collapse that might be caused by the surface tensions of the liquid surfaces LS1 and LS2 can be suppressed.

The substrate processing method further includes a process S104 of replacing the previously formed liquid film LF2 of the rinse liquid L2 with the liquid film LF3 of the drying liquid L3 (see FIG. 3). In this process S104, the drying liquid discharge nozzle 33 is disposed directly above the central portion of the substrate 2 instead of the rinse liquid discharge nozzle 32 (see FIG. 4C). The discharge of the rinse liquid L2 from the rinse liquid discharge nozzle 32 is stopped, and the discharge of the drying liquid L3 from the drying liquid discharge nozzle 33 is begun. The drying liquid L3 is supplied onto the central portion of the substrate 2 being rotated along with the substrate holder 10 and diffused on the entire top surface 2a of the substrate 2 by the centrifugal force, so that the liquid film LF3 is formed. Accordingly, the rinse liquid L2 remaining in the irregularity pattern 4 is replaced by the drying liquid L3. The rotation number of the substrate holder 10 and the feed flow rate of the drying liquid L3 are set such that the heights of the liquid surfaces LS2 and LS3 are maintained higher than the height of the upper end 5a (see FIG. 6) of the recess 5 during the replacement of the rinse liquid L2 by the drying liquid L3. Thus, the pattern collapse that might be caused by the surface tensions of the liquid surfaces LS2 and LS3 can be suppressed.

The substrate processing method further includes a process S105 of forming the exposed portion 6 of the irregularity pattern 4 (see FIG. 3). In this process S105, not only the exposed portion 6 but also the boundary portion 8 between the exposed portion 6 and the covered portion 7 is formed. Accordingly, in this process S105, the exposed portion 6, the covered portion 7 and the boundary portion 8 are formed. In the process S105, from a time t0 to a time t1 shown in FIG. 7, the drying liquid discharge nozzle 33 is slightly moved outwards from directly above the central portion of the substrate 2 in the diametrical direction while discharging the drying liquid L3.

Subsequently, from the time t1 to a time t2 shown in FIG. 7, the vertical nozzle 51 is positioned directly above the central portion of the substrate 2 instead of the drying liquid discharge nozzle 33, and the vertical nozzle 51 discharges the gas G1 (see FIG. 4D). After the discharge toward the substrate 2, the gas G1 is uniformly diffused in a radial shape along the substrate 2. Therefore, the exposed portion 6 having a circular shape concentric with the substrate 2 can be formed at the central portion of the substrate 2.

Further, from the time t1 to the time t2 shown in FIG. 7, the heating liquid discharge nozzle 73 is positioned directly under the central portion of the substrate 2, and the heating liquid discharge nozzle 73 discharges the heating liquid L4 (see FIG. 4D). Since the heating liquid L4 heats the central portion of the substrate 2, the exposed portion 6 having the circular shape concentric with the substrate 2 can be formed.

The vertical nozzle 51 and the heating liquid discharge nozzle 73 form the exposed portion 6 having the circular shape concentric with the substrate 2 at the central portion of the substrate 2. Further, either the vertical nozzle 51 or the heating liquid discharge nozzle 73 may be used for the formation of the exposed portion 6.

Further, in FIG. 7, a time when the vertical nozzle 51 starts the discharge of the gas G1 is the same as the time t1 when the temporary movement of the drying liquid discharge nozzle 33 is ended. However, the time when the vertical nozzle 51 starts the discharge of the gas G1 may be ahead of the time t1 as long as it is after the time t0 when the temporary movement of the drying liquid discharge nozzle 33 is begun. A space for accommodating the vertical nozzle 51 needs to be provided directly above the central portion of the substrate 2.

Moreover, in FIG. 7, a time when the heating liquid discharge nozzle 73 starts the heating of the substrate 2 is the same as the time t1 when the temporary movement of the drying liquid discharge nozzle 33 is ended. However, the time when the heating liquid discharge nozzle 73 starts the heating of the substrate 2 may be prior to the time t1, or may be the same as or prior to the time t0.

The substrate processing method includes a process S106 of enlarging the exposed portion 6 by moving the boundary portion 8 (see FIG. 3). In this process 106, from the time t2 to the time t4 in FIG. 7, the liquid controller 96 moves the drying liquid discharge nozzle 33 from the inner side of the substrate 2 toward the outer side of the substrate 2 in the diametrical direction thereof while discharging the drying liquid L3 from the drying liquid discharge nozzle 33 (see FIG. 5A and FIG. 5B). After supplied onto the substrate 2, the drying liquid L3 is diffused outwards in the diametrical direction of the substrate 2 by the centrifugal force to be scattered from the edge of the substrate 2. Since the liquid controller 96 supplies the drying liquid L3 onto the substrate 2 from the drying liquid discharge nozzle 33 from the time t2 to the time t4, the edge portion of the substrate 2 can be coated with the drying liquid L3. Further, from the time t2 to the time t4, since the liquid controller 96 moves the drying liquid discharge nozzle 33 from the inner side of the substrate 2 toward the outer side of the substrate 2 in the diametrical direction thereof, the boundary portion 8 can be moved from the inner side of the substrate 2 toward the outer side of the substrate 2 in the diametrical direction thereof. The boundary portion 8 is formed at an inner position than the discharge opening 33a of the drying liquid discharge nozzle 33 in the diametrical direction of the substrate 2.

From the time t2 to the time t3 shown in FIG. 7, the gas controller 97 moves the vertical nozzle 51 from the inner side of the substrate 2 toward the outer side of the substrate 2 in the diametrical direction thereof while pressing the boundary portion 8 by discharging the gas G1 from the vertical nozzle 51 (see FIG. 5A). Further, from the time t3 to the time t4 shown in FIG. 7, the gas controller 97 moves the inclined nozzle 52 from the inner side of the substrate 2 toward the outer side of the substrate 2 in the diametrical direction thereof while pressing the boundary portion 8 by discharging the gas G2 from the inclined nozzle 52 instead of the vertical nozzle 51 (see FIG. 5B).

By pressing the boundary portion 8 by using the inclined nozzle 52 instead of the vertical nozzle 51, it is possible to press the boundary portion 8 efficiently. Since the gas G2 discharged from the inclined nozzle 52 has a horizontal component as well as a vertical component, the boundary portion 8 can be pressed efficiently.

Furthermore, though the gas controller 97 stops the discharge of the gas G1 from the vertical nozzle 51 and starts the discharge of the gas G2 from the inclined nozzle 52 concurrently at the time t3 shown in FIG. 7, the discharge of the gas G2 from the inclined nozzle 52 may be begun before the discharge of the gas G1 from the vertical nozzle 51 is stopped. By pressing the boundary portion 8 with the gas G1 and the gas G2, the boundary portion 8 can be pressed continuously. The gas controller 97 needs to start the discharge of the gas G2 from the inclined nozzle 52 after the discharge of the gas G1 from the vertical nozzle 51 is begun, that is, after the exposed portion 6 having the circular shape concentric with the substrate 2 is formed.

From the time t2 to the time t4 shown in FIG. 7, the heating controller 98 moves the heating position P in the moving direction of the boundary portion 8 while overlapping the heating position P with the boundary portion 8 when viewed from the vertical direction (see FIG. 5A and FIG. 5B). The heating controller 98 may move the heating position P by moving the heating liquid discharge nozzle 73.

Further, from the time t2 to the time t4 shown in FIG. 7, the heating liquid discharge nozzle 73 is moved in the moving direction of the boundary portion 8, for example, in the diametrical direction of the substrate 2 at the same time and at the same speed as the drying liquid discharge nozzle 33, the vertical nozzle 51 and the inclined nozzle 52.

The heating liquid discharge nozzle 73, the drying liquid discharge nozzle 33, the vertical nozzle 51 and the inclined nozzle 52 need to be moved in the diametrical direction of the substrate 2, and may be moved in different directions from the center of the substrate 2 or in the same direction therefrom.

Further, the heating liquid discharge nozzle 73, the drying liquid discharge nozzle 33, the vertical nozzle 51 and the inclined nozzle 52 need to be moved at the same time and at the same speed, and this moving speed may be varied with a lapse of time, which will be described in detail later.

If the drying liquid discharge nozzle 33 reaches the position directly above the edge portion of the substrate 2 shortly before the time t4 shown in FIG. 7, the liquid controller 96 stops the discharge of the drying liquid L3 from the drying liquid discharge nozzle 33 at the time t4. Then, from the time t4 to the time t5, the gas controller 97 moves the inclined nozzle 52 in the moving direction of the boundary portion 8 while pressing the boundary portion 8 by discharging the gas G2 from the inclined nozzle 52 (see FIG. 5C). Further, from the time t4 to the time t5, the heating controller 98 moves, while discharging the heating liquid L4 from the heating liquid discharge nozzle 73, the heating liquid discharge nozzle 73 in the moving direction of the boundary portion 8 such that the heating liquid discharge nozzle 73 and the boundary portion 8 are overlapped with each other when viewed from the vertical direction (see FIG. 5C). As a result, the exposed portion 6 is further enlarged.

Here, the gas controller 97 may move the vertical nozzle 51 in the moving direction of the boundary portion 8 while pressing the boundary portion 8 by discharging the gas G1 from the vertical nozzle 51 from the time t3 until the time t5 as well as from the time t2 to the time t3 shown in FIG. 7.

Shortly before the time t5 shown in FIG. 7, when the heating liquid discharge nozzle 73 reaches the position directly under the edge portion of the substrate 2, the inclined nozzle 52 forms, above the edge portion of the substrate 2, the gas flow which flows from the inner side of the substrate 2 toward the outer side of the substrate 2 in the diametrical direction thereof as it flows downwards (see FIG. 5D). Accordingly, the heating liquid L4 supplied to the bottom surface 2b of the substrate 2 can be suppressed from reaching the top surface 2a of the substrate 2 at the edge portion of the substrate 2. Thus, contamination (for example, particle adhesion) of the top surface 2a of the substrate 2 can be suppressed.

At the time t5 shown in FIG. 7, the heating controller 98 stops the discharge of the heating liquid L4 from the heating liquid discharge nozzle 73, and, then, at the time t6, the gas controller 97 stops the discharge of the gas G2 from the inclined nozzle 52. By stopping the discharge of the gas G2 after stopping the discharge of the heating liquid L4, the heating liquid L4 can be suppressed from reaching the top surface 2a of the substrate 2 so that the contamination of the top surface 2a of the substrate 2 can be suppressed.

The substrate processing method includes a process S107 of carrying the processed substrate 2 to the outside of the substrate processing apparatus 1 (see FIG. 3). The substrate holder 10 releases the holding of the substrate 2, and the non-illustrated transfer device receives the substrate 2 from the substrate holder 10 and takes the received substrate 2 to the outside of the substrate processing apparatus 1.

As stated above, according to the present exemplary embodiment, the heating controller 98 moves the hating position P in the moving direction of the boundary portion 8 while overlapping the heating position P with the boundary portion 8 when viewed from the vertical direction. By way of example, the heating controller 98 moves the heater 72 in the moving direction of the boundary portion 8 such that the heater 72 and the boundary portion 8 are overlapped with each other when viewed from the vertical direction. As a result, regardless of where the boundary portion 8 reaches, it is possible to heat the boundary portion 8 intensively. The exposed portion 6 and the covered portion 7 are hardly heated by the heating liquid L4. Effects of this will be discussed for the following two cases (1) and (2).

(1) If the temperature of the drying liquid L3 discharged from the drying liquid discharge nozzle 33 is set to be higher than the room temperature, the following effects are obtained. Since heating energy can be concentrated to the drying liquid L3 existing at the boundary portion 8, heat lost by the vaporization of the drying liquid L3 at the boundary portion 8 can be replenished, so that a temperature decline of the drying liquid L3 at the boundary portion 8 can be suppressed. Therefore, a decrease of the surface tension of the drying liquid L3 at the boundary portion 8 can be diminished, so that the pattern collapse can be suppressed.

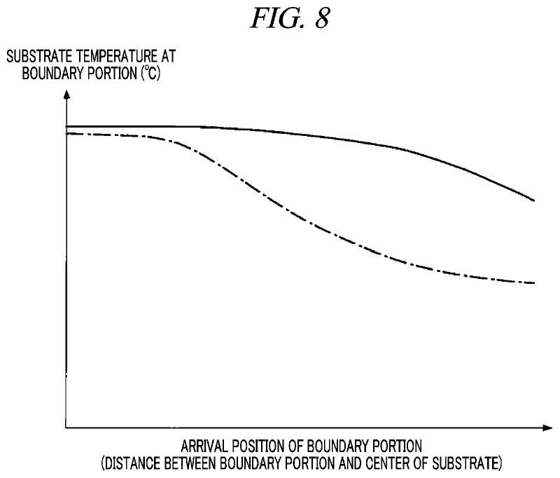

FIG. 8 is a diagram showing a relationship between an arrival position of the boundary portion and a substrate temperature at the boundary portion according to the first exemplary embodiment. In FIG. 8, a solid line shows a result of an experimental example where the heating position P is moved in the moving direction of the boundary portion 8 while overlapping the heating position P with the boundary portion 8 from the time t2 until the time t5 shown in FIG. 7. The moving direction of the boundary portion 8 is a direction in which the exposed portion 6 is enlarged and is a direction from the inner side of the substrate 2 toward the outer side of the substrate 2 in the diametrical direction thereof. Meanwhile, in FIG. 8, a dashed dotted line shows a result of a comparative example where the heating position P is fixed at the central portion of the substrate 2 from the time t2 to the time t5 shown in FIG. 7. The experimental example and the comparative example shown in FIG. 8 are conducted under the same conditions except the presence/absence of the movement of the heating liquid discharging nozzle 73. Further, in FIG. 8, the temperature of the drying liquid L3 discharged from the drying liquid discharge nozzle 33 is set to be slightly lower than the boiling potion of the drying liquid L3.

As can be clearly seen from FIG. 8, according to the experimental example, the temperature decrease of the boundary portion 8 can be suppressed during the movement of the boundary portion 8, as compared to the comparative example. Particularly, the temperature decrease of the boundary portion 8 at the moment when the boundary portion 8 has reached the edge portion of the substrate 2 can be suppressed. Further, as for the reason why the temperature of the edge portion of the substrate 2 easily decreases, since a circumferential speed of the substrate 2 at the edge portion of the substrate 2 is larger than a circumferential speed of the substrate 2 at the central portion of the substrate 2, the centrifugal force is larger at the edge portion of the substrate 2. As a result, the liquid film LF3 of the drying liquid L3 is thinner at the edge portion of the substrate 2. Therefore, the drying liquid L3 may easily vaporize, so that the heat is easily lost by the vaporization.

(2) If the temperature of the drying liquid L3 discharged from the drying liquid discharge nozzle 33 is set to be the room temperature, the following effects are obtained. Since the heating energy can be concentrated to the drying liquid L3 which exists at the boundary portion 8, a temperature difference between the boundary portion 8 and the covered portion 7 (particularly, the edge portion of the substrate 2) can be increased. At the boundary portion 8, since the temperature of the drying liquid L3 can be set to be higher than the room temperature, the surface tension of the drying liquid L3 can be reduced, so that the pattern collapse can be suppressed. Meanwhile, at the edge portion of the substrate 2, since the temperature of the drying liquid L3 can be maintained at the room temperature in a stage before the boundary portion 8 reaches the edge portion of the substrate 2, the vaporization of the drying liquid L3 can be suppressed.

As the circumferential speed of the substrate 2 at the edge portion of the substrate 2 is larger than that of the central portion of the substrate 2, the centrifugal force is large at the edge portion of the substrate 2, so that the liquid film LF3 of the drying liquid L3 is thin thereat. Therefore, suppressing the vaporization of the drying liquid L3 at the edge portion of the substrate 2 is important to suppress unintentional exposure of the edge portion of the substrate 2 from the drying liquid L3 in the stage before the boundary portion 8 reaches the edge portion of the substrate 2. If the edge portion of the substrate 2 is exposed from the drying liquid L3 in the stage before the boundary portion 8 reaches the edge portion of the substrate 2, a particle may adhere to the edge portion of the substrate 2. The particle is formed by mist of the drying liquid L3 or the like. According to the present exemplary embodiment, since the unintentional exposure of the edge portion of the substrate 2 from the drying liquid L3 can be suppressed in the stage before the boundary portion 8 reaches the edge portion of the substrate 2, the particle adhesion can be suppressed. Furthermore, according to the present exemplary embodiment, since the unintentional exposure of the edge portion of the substrate 2 from the drying liquid L3 can be suppressed in the stage before the boundary portion 8 reaches the edge portion of the substrate 2, the pattern collapse can be suppressed. If the edge portion of the substrate 2 is dried unintentionally and thus the drying liquid L3 exists sparsely, there is a concern that the surface tension of the drying liquid L3 may act on the boundary portion 8, resulting in the pattern collapse.

As stated above, to increase the temperature difference between the boundary portion 8 and the covered portion 7 (particularly, the edge portion of the substrate 2) for the purpose of suppressing the particle adhesion, the drying liquid discharge nozzle 33 may discharge the drying liquid L3 of the room temperature. Conventionally, to suppress a pattern collapse during the drying processing, the drying liquid discharge nozzle 33 discharges the drying liquid L3 having a temperature higher than the room temperature. It is because as the temperature of the drying liquid L3 increases, the surface tension of the drying liquid L3 is reduced, and, thus, a stress applied to the irregularity pattern 4 is reduced. According to the exemplary embodiment, however, to suppress the pattern collapse and the particle adhesion, a technique of locally heating the boundary portion 8 and discharging the drying liquid L3 of the room temperature from the drying liquid discharge nozzle 33 is provided.

Further, according to the present exemplary embodiment, the heating controller 98 moves the heating position P from the inner side of the substrate 2 toward the outer side of the substrate 2 in the diametrical direction thereof, while the rotation controller 95 rotates the substrate 2 along with the substrate holder 10. The boundary portion 8 can be moved from the inner side of the substrate 2 toward the outer side of the substrate 2 in the diametrical direction thereof so as not to be against the centrifugal force.

The boundary portion 8 is formed to have a ring shape. Therefore, as the boundary portion 8 is moved from the inner side of the substrate 2 toward the outer side of the substrate 2 in the diametrical direction thereof, a length of the circumference of the boundary portion 8 is lengthened. Thus, the heater 72 heats the larger boundary portion 8 as it is moved from the inner side of the substrate 2 toward the outer side of the substrate 2 in the diametrical direction thereof.

In view of this, the heating controller 98 may perform a control of keeping constant a total heating amount per unit area (unit: J/mm²) on the heating surface (for example, the bottom surface 2b of the substrate 2) heated by the heater 72 in the period during which the heating position P is moved from the inner side of the substrate 2 toward the outer side of the substrate 2 in the diametrical direction thereof. Here, the term “constant” implies that the heating amount falls within a range defined by an upper limit and a lower limit. As a specific example of this control, controls of (A) to (C) to be described below may be performed. The controls of (A) to (C) may be performed individually or in multiple combinations.

(A) The heating controller 98 slows down a moving speed of the heating position P in the diametrical direction of the substrate 2 as the heating position P is moved from the inner side of the substrate 2 toward the outer side of the substrate 2 in the diametrical direction thereof. By way of example, as the heater 72 is moved from the inner side of the substrate 2 toward the outer side of the substrate 2 in the diametrical direction thereof, the heating controller 98 slows down the moving rate at which the heater 72 is moved in the diametrical direction of the substrate 2. Accordingly, the total heating amount per unit area can be uniformed in the entire diametrical direction of the substrate 2, so that a temperature variation of the boundary portion 8 that might be caused by a variation in the length of the circumference of the boundary portion 8 can be suppressed.

(B) The rotation controller 95 reduces the rotation number of the substrate holder 10 as the heating controller 98 moves the heating position P from the inner side of the substrate 2 toward the outer side of the substrate 2 in the diametrical direction thereof. By way of example, the rotation controller 95 reduces the rotation number of the substrate holder 10 as the heating controller 98 moves the heater 72 from the inner side of the substrate 2 toward the outer side of the substrate 2 in the diametrical direction thereof. Accordingly, the total heating amount per unit area can be uniformed in the entire diametrical direction of the substrate 2, so that the temperature variation of the boundary portion 8 that might be caused by the variation in the length of the circumference of the boundary portion 8 can be suppressed.

(C) The heating controller 98 increases a heating amount per unit time (unit: W) as the heating position P is moved from the inner side of the substrate 2 toward the outer side of the substrate 2 in the diametrical direction thereof. By way of example, the heating controller 98 increases the temperature of the heating liquid L4 discharged from the heating liquid discharge nozzle 73 as the heating position P is moved from the inner side of the substrate 2 toward the outer side of the substrate 2 in the diametrical direction thereof. The heating controller 98 may increase a flow rate (unit: mL/sec) of the heating liquid L4 discharged from the heating liquid discharge nozzle 73 as the heating position P is moved from the inner side of the substrate 2 toward the outer side of the substrate 2 in the diametrical direction thereof. Accordingly, the total heating amount per unit area can be uniformed in the entire diametrical direction of the substrate 2, so that the temperature variation of the boundary portion 8 that might be caused by the variation in the length of the circumference of the boundary portion 8 can be suppressed.

According to the present exemplary embodiment, the liquid controller 96 discharges the drying liquid L3 from the drying liquid discharge nozzle 33, and moves the drying liquid discharge nozzle 33 in the moving direction of the boundary portion 8 while locating the discharge opening 33a of the drying liquid discharge nozzle 33 at an outer position than the boundary portion 8 in the diametrical direction of the substrate 2. Since the drying liquid L3 is not supplied to the inner portion of the substrate 2 inner than the boundary portion 8 in the diametrical direction of the substrate 2, it is possible to suppress the boundary portion 8 from being moved in a direction opposite to the direction in which the exposed portion 6 is enlarged. Further, since the drying liquid L3 is supplied to the outer portion than the boundary portion 8 in the diametrical direction of the substrate 2, unintentional exposure of the edge portion of the substrate 2 from the drying liquid L3 can be suppressed in the stage before the boundary portion 8 reaches the edge portion of the substrate 2. Therefore, the pattern collapse can be suppressed, and the particle adhesion can also be suppressed.

According to the present exemplary embodiment, the heating position mover 80 includes the heater moving mechanism 81 configured to move the heating position P by moving the heater 72. Since multiple positions distanced apart from each other in the moving direction of the heating position P can be heated by the single heater 72, the number of the heater 72 required to be provided can be reduced.

According to the present exemplary embodiment, while the liquid controller 96 stops the supply of the drying liquid L3 onto the substrate 2 and the heating controller 98 supplies the heating liquid L4 to the edge portion of the substrate 2, the gas controller 97 forms the flow of the gas G2 above the edge portion of the substrate 2, as shown in FIG. 5D. As the gas G2 flows downwards, it flows from the inner side of the substrate 2 toward the outer side of the substrate 2 in the diametrical direction thereof. Since the pressure of the flow of the gas G2 is set such that the gas G2 flows outwards in the diametrical direction of the substrate 2, the heating liquid L4 supplied to the bottom surface 2b of the substrate 2 in the edge portion of the substrate 2 can be efficiently suppressed from reaching the top surface 2a of the substrate 2, so that the contamination (for example, particle adhesion) of the top surface 2a of the substrate 2 can be efficiently suppressed.

In the above-stated first exemplary embodiment, the heating controller 98 stops the supply of the heating liquid L4 after the liquid controller 96 stops the supply of the drying liquid L3, as shown in FIG. 7. Since the boundary portion 8 has not reached the edge portion of the substrate 2 when the supply of the drying liquid L3 is stopped, the edge portion of the substrate 2 is not heated by the heating liquid L4. For the purpose of heating the edge portion of the substrate 2 by the heating liquid L4, the supply of the heating liquid L4 is stopped after the supply of the drying liquid L3 is stopped.

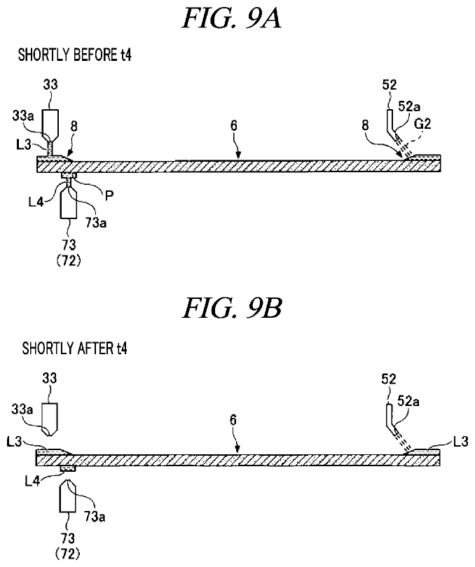

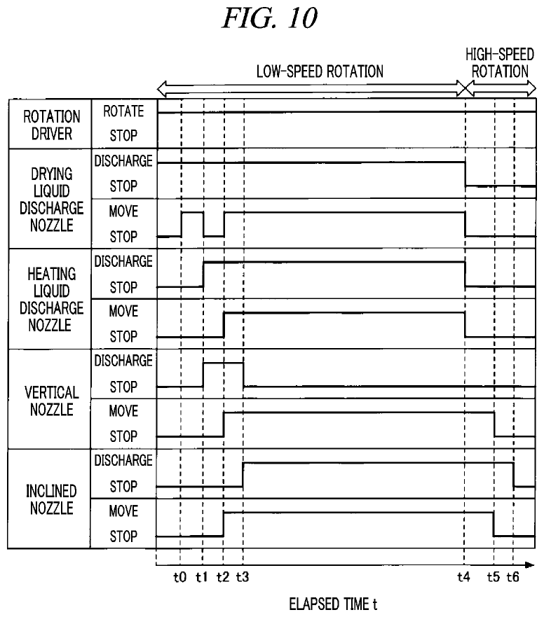

Meanwhile, in a second exemplary embodiment to be described below, the heating controller 98 stops the supply of the heating liquid L4 at the same time as the liquid controller 96 stops the supply of the drying liquid L3, as illustrated in FIG. 9A to FIG. 10. If the supply of the drying liquid L3 onto the top surface 2a of the substrate 2 is stopped, the heating liquid L4 flown to the top surface 2a of the substrate 2 from the bottom surface 2b thereof cannot be pushed back by the drying liquid L3 later. For the purpose of restricting the inflow of the heating liquid L4, the supply of the heating liquid L4 is stopped at the same time when the supply of the drying liquid L3 is stopped. Hereinafter, the second exemplary embodiment will be described, focusing on distinctive features from the first exemplary embodiment.

FIG. 9A and FIG. 9B are diagrams illustrating parts of a substrate processing according to the second exemplary embodiment. FIG. 9A is a diagram illustrating a state shortly before the supplies of the drying liquid and the heating liquid are stopped according to the second exemplary embodiment. FIG. 9B is a diagram illustrating a state immediately after the supplies of the drying liquid and the heating liquid are stopped according to the second exemplary embodiment. FIG. 10 is a timing charts showing operations of the rotation driver, the drying liquid discharge nozzle, the heating liquid discharge nozzle, the vertical nozzle and the inclined nozzle according to the second exemplary embodiment.

If the drying liquid discharge nozzle 33 reaches the position directly above the edge portion of the substrate 2 shortly before a time t4 shown in FIG. 10, the liquid controller 96 stops the discharge of the drying liquid L3 from the drying liquid discharge nozzle 33 at the time t4 (see FIG. 9A and FIG. 9B). Concurrently, the heating controller 98 stops the discharge of the heating liquid L4 from the heating liquid discharge nozzle 73 (see FIG. 9A and FIG. 9B). Still concurrently, the rotation controller 95 increases the rotation number of the substrate holder 10 (see FIG. 10).

As described above, according to the present exemplary embodiment, the heating controller 98 stops the supply of the heating liquid L4 and the rotation controller 95 increases the rotation number of the substrate holder 10 at the same time as the liquid controller 96 stops the supply of the drying liquid L3. Accordingly, since the rotation number of the substrate 2 is increased, a large centrifugal force acts on the drying liquid L3 and the heating liquid L4 remaining on the substrate 2. The drying liquid L3 and the heating liquid L4 remaining on the substrate 2 are scattered outwards from the edge of the substrate 2 in the diametrical direction of the substrate 2 by the large centrifugal force. Therefore, introduction of the heating liquid L4 onto the top surface 2a of the substrate 2 from the bottom surface 2b thereof can be suppressed.

Furthermore, according the present exemplary embodiment, although the rotation number of the substrate holder 10 is increased at the same time as the supplies of the drying liquid L3 and the heating liquid L4 are stopped, as shown in FIG. 10, a timing of increasing the rotation number of the substrate holder 10 and a timing of stopping the supplies of the drying liquid L3 and the heating liquid L4 may be slightly different as long as the drying liquid L3 and the heating liquid L4 remaining on the substrate 2 can be scattered off by the large centrifugal force after the supplies of the drying liquid L3 and the heating liquid L4 are stopped, and, also, as long as the introduction of the heating liquid L4 onto the top surface 2a of the substrate 2 from the bottom surface 2b thereof can be suppressed.

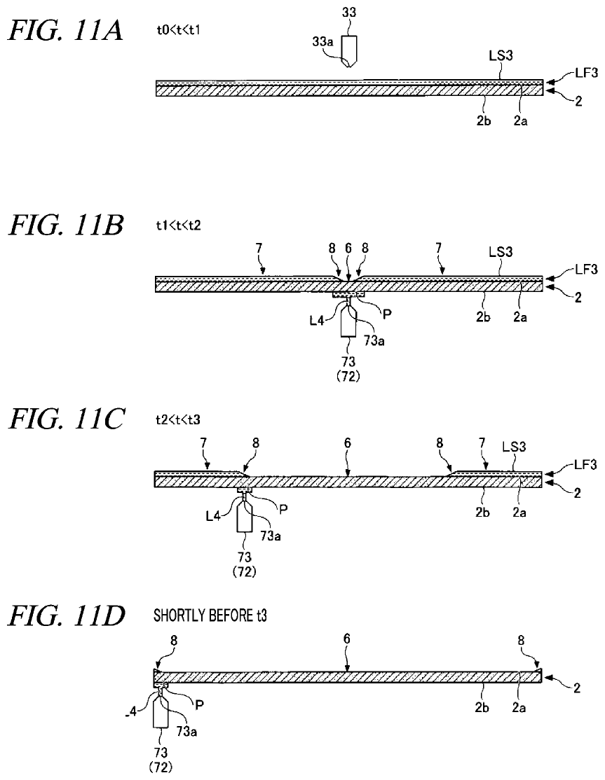

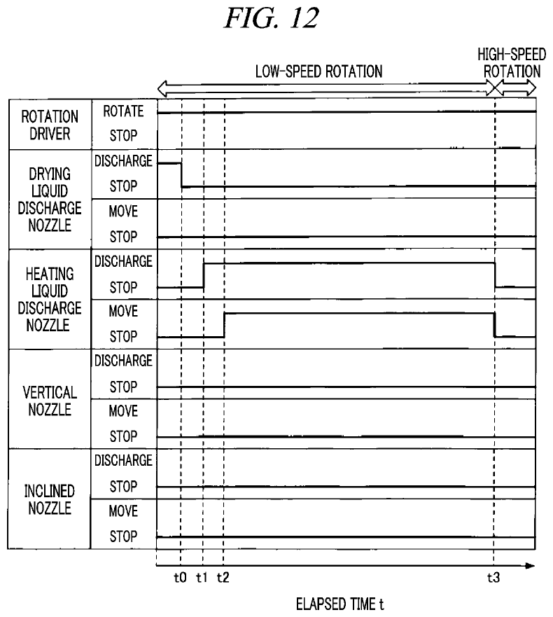

FIG. 11A to FIG. 11D are diagrams illustrating parts of a substrate processing according to a third exemplary embodiment. FIG. 11A is a diagram showing a state when the supply of the drying liquid is stopped according to the third exemplary embodiment, and FIG. 11B is a diagram showing a state where the exposed portion is formed at the central portion of the liquid film of the drying liquid according to the third exemplary embodiment. FIG. 11C is a diagram showing a state during the enlargement of the exposed portion according to the third exemplary embodiment, and FIG. 11D is a diagram showing a state shortly before the enlargement of the exposed portion is completed according to the third exemplary embodiment. FIG. 12 is a timing chart showing operations of the rotation driver, the drying liquid discharge nozzle, the heating liquid discharge nozzle, the vertical nozzle and the inclined nozzle according to the third exemplary embodiment. Hereinafter, the present exemplary embodiment will be described, focusing on distinctive features from the first and second exemplary embodiments.

In the process S105 (see FIG. 3) of forming the exposed portion 6 of the irregularity pattern 4, the liquid controller 96 first stops the discharge of the drying liquid L3 from the drying liquid discharge nozzle 33 at a time t0 shown in FIG. 12, thus stopping the supply of the drying liquid L3 onto the substrate 2. Until shortly before the time t0, the drying liquid discharge nozzle 33 discharges the drying liquid L3 of the room temperature, and the liquid film LF3 of the drying liquid L3 of the room temperature is formed at the time t0. Still after the time t0, the rotation controller 95 rotates the substrate holder 10 such that the liquid film LF3 of the drying liquid L3 of the room temperature covers the entire top surface 2a of the substrate 2 (see FIG. 11A). The rotation number of the substrate holder 10 may be in a range from, e.g., 200 rpm to 1000 rpm.

Then, from a time t1 to a time t2 shown in FIG. 12, the heating liquid discharge nozzle 73 is disposed directly under the central portion of the substrate 2, and the heating liquid discharge nozzle 73 heats the central portion of the substrate 2 (see FIG. 11B). The exposed portion 6 having the circular shape concentric with the substrate 2 is formed at the central portion of the substrate 2. At this time, the boundary portion 8 between the exposed portion 6 and the covered portion 7 is pushed outwards in the diametrical direction of the substrate 2 by the centrifugal force not to be moved inwards in the diametrical direction of the substrate 2. The rotation number of the substrate holder 10 may be in the range from, e.g., 200 rpm to 1000 rpm.

Further, in FIG. 12, the time t1 when the heating of the central portion of the substrate 2 is begun is after the time t0 when the supply of the drying liquid L3 onto the substrate 2 is stopped. However, the time t1 may be at the same time as or before the time t0.

In the process S106 of enlarging the exposed portion 6 (see FIG. 3), the heating controller 98 moves the heating liquid discharge nozzle 73 from a time t2 to a time t3 shown in FIG. 12 (see FIG. 11C). In the meantime, the rotation controller 95 rotates the substrate holder 10.

While heating the liquid film LF3 by the heating liquid discharge nozzle 73, the heating controller 98 moves the heating liquid discharge nozzle 73 in the moving direction of the boundary portion 8 such that the heating position P and the boundary portion 8 are overlapped with each other when viewed from the vertical direction (see FIG. 11C). At this time, the boundary portion 8 is pushed outwards in the diametrical direction by the centrifugal force not to be moved inwards in the diametrical direction. The rotation number of the substrate holder 10 is in the range from, e.g., 200 rpm to 1000 rpm.

If the heating liquid discharge nozzle 73 reaches a position directly above the edge portion of the substrate 2 shortly before the time t3 shown in FIG. 12, the boundary portion 8 reaches the edge portion of the substrate 2 (see FIG. 11D). Then, the boundary portion 8 disappears by the vaporization of the drying liquid L3, and the heating controller 98 turns the heating liquid discharge nozzle 73 from an operating state to a stopped state at the time t3.

Further, the rotation controller 95 increases the rotation number of the substrate holder 10 at the time t3 shown in FIG. 12. The rotation number of the substrate holder 10 ranges from, e.g., 1000 rpm to 2000 rpm. Since the rotation number of the substrate 2 is increased, a large centrifugal force acts on the drying liquid L3 remaining on the substrate 2, so that the drying liquid L3 is scattered outwards from the edge of the substrate 2 in the diametrical direction of the substrate 2. Thereafter, the substrate 2 is carried out of the substrate processing apparatus 1.

The time when the high-speed rotation of the substrate holder 10 is begun is the same as the time when the boundary portion 8 reaches the edge portion of the substrate 2, the time when the high-speed rotation of the substrate holder 10 is begun may be after the time when the boundary portion 8 reaches the edge portion of the substrate 2. Before the boundary portion 8 arrives at the edge portion of the substrate 2, the low-speed rotation of the substrate holder 10 is performed to allow the liquid film LF3 of the drying liquid L3 formed on the substrate 2 not to be removed by the centrifugal force.

As stated above, according to the present exemplary embodiment, the heating controller 98 moves the heating position P in the moving direction of the boundary portion 8 while overlapping the heating position P with the boundary portion 8, the same as in the first and second exemplary embodiments. By way of example, the heating controller 98 moves the heating liquid discharge nozzle 73 in the moving direction of the boundary portion 8 such that the heating liquid discharge nozzle 73 and the boundary portion 8 are overlapped with each other when viewed from the vertical direction. As a result, regardless of where the boundary portion 8 reaches, it is possible to heat the boundary portion 8 intensively. The exposed portion 6 and the covered portion 7 are hardly heated by the heating liquid L4. In the present exemplary embodiment, since the liquid film LF3 of the drying liquid L3 having the room temperature is formed, the same effects as those obtained when forming the liquid film LF3 of the drying liquid L3 of the room temperature in the first and second exemplary embodiments can be achieved.

That is, since the boundary portion 8 can be heated intensively, the temperature difference between the boundary portion 8 and the covered portion 7 (particularly, the edge portion of the substrate 2) can be increased. At the boundary portion 8, since the temperature of the drying liquid L3 can be set to be higher than the room temperature, the surface tension of the drying liquid L3 can be reduced, so that the pattern collapse can be suppressed. Meanwhile, at the edge portion of the substrate 2, the unintentional vaporization of the drying liquid L3 and the unintentional exposure of the drying liquid L3 can be suppressed. Therefore, the pattern collapse can be suppressed and the particle adhesion can be suppressed.

According to the present exemplary embodiment, as in the first and second exemplary embodiment, the heating controller 98 moves the heating position P from the inner side of the substrate 2 toward the outer side of the substrate 2 in the diametrical direction thereof, while the rotation controller 95 rotates the substrate 2 along with the substrate holder 10. The boundary portion 8 can be moved from the inner side of the substrate 2 toward the outer side of the substrate 2 in the diametrical direction thereof so as not to be against the centrifugal force.

The heating controller 98 may perform a control of keeping constant a total heating amount per unit area (unit: J/mm²) on a heating surface (for example, the bottom surface 2b of the substrate 2) in a period during which the heating position P is moved from the inner side of the substrate 2 toward the outer side of the substrate 2 in the diametrical direction thereof. As a specific example of this control, the above-stated controls of (A) to (C) may be performed. The controls of (A) to (C) may be performed individually or in multiple combinations.

According to the present exemplary embodiment, unlike in the first and second exemplary embodiments, while the heating controller 98 moves the heating position P, the liquid controller 96 stops the discharge of the drying liquid L3 of the room temperature from the drying liquid discharge nozzle 33. Since the supply of the drying liquid L3 onto the substrate 2 is stopped, an operation of moving the drying liquid discharge nozzle 33 in the moving direction of the boundary portion 8 while placing the discharge opening 33a of the drying liquid discharge nozzle 33 at a position outer than the boundary portion 8 in the diametrical direction of the substrate 2 is not necessary. Thus, it is not needed to move the drying liquid discharge nozzle 33 in conjunction with the heating position P, and the position of the boundary portion 8 can be controlled with high accuracy. It is because the heating position P becomes the position of the boundary portion 8. The boundary portion 8 is moved to be overlapped with the heating position P by being moved outwards in the diametrical direction by the centrifugal force so as not to be moved inwards in the diametrical direction. Furthermore, to control the position of the boundary portion 8 with higher accuracy, the discharges of the gases G1 and G2 from the gas supply unit 50 are stopped while the boundary portion 8 is moved (see FIG. 12).

According to the present exemplary embodiment, unlike in the first and second exemplary embodiments, the supply of the drying liquid L3 onto the substrate 2 is stopped while the boundary portion 8 is moving, so that the drying liquid L3 is not supplied. Therefore, it is important to suppress the vaporization of the drying liquid L3 at the edge portion of the substrate 2 in the stage before the boundary portion 8 reaches the edge portion of the substrate 2. To suppress the vaporization of the drying liquid L3, the drying liquid L3 having the room temperature is used.

According to the present exemplary embodiment, the same as in the first and second exemplary embodiments, the heating position mover 80 includes a heater moving mechanism 81 configured to move the heating position P by moving the heating liquid discharge nozzle 73. Since multiple positions distanced apart from each other in the moving direction of the heating position P can be heated by the single heating liquid discharge nozzle 73, the number of the heating liquid discharge nozzle 73 required to be provided can be reduced.

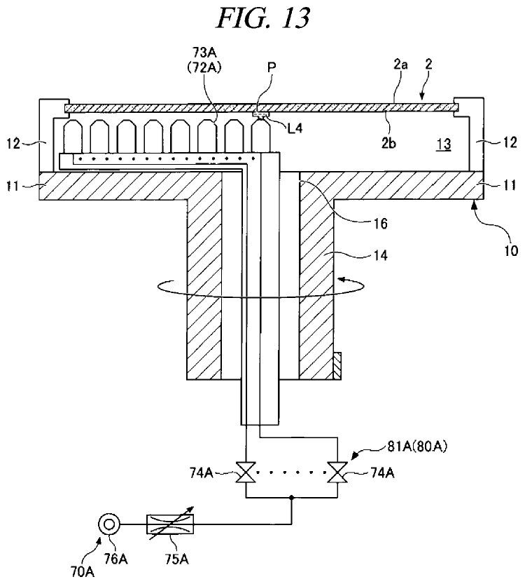

FIG. 13 is a diagram illustrating a substrate holder and a heating unit according to a fourth exemplary embodiment. Hereinafter, the fourth exemplary embodiment will be described, focusing on distinctive features from the first to third exemplary embodiments. A heating unit 70A according to the fourth exemplary embodiment is used instead of the heating unit 70 in the first to third exemplary embodiments.

The heating unit 70A according to the present exemplary embodiment includes a multiple number of heaters 72A and a heating position mover 80A. Each of the multiple number of heaters 72A is equipped with a heating liquid discharge nozzle 73A configured to discharge the heating liquid L4. These heaters 72A heat different positions in the moving direction of the boundary portion 8 (see FIG. 6). The heaters 72A are arranged, for example, in the diametrical direction of the substrate 2 and heats the substrate 2 ranging from the central portion to the edge portion thereof.

The heating liquid discharge nozzle 73A is connected to a supply source 76A via an opening/closing valve 74A and a flow rate control valve 75A. If the opening/closing valve 74A opens a flow path for the heating liquid L4, the heating liquid L4 is discharged from the heating liquid discharge nozzle 73A. Meanwhile, if the opening/closing valve 74A closes the flow path for the heating liquid L4, the discharge of the heating liquid L4 from the heating liquid discharge nozzle 73A is stopped.

The opening/closing valve 74A is provided for each corresponding heating liquid discharge nozzle 73A. These multiple number of heating liquid discharge nozzles 73A are connected to different opening/closing valves 74A, and are capable of discharging the heating liquid L4 at different timings. These heating liquid discharge nozzles 73A are connected to a common supply source 76A via a common flow rate control valve 75A.

Further, the flow rate control valve 75A may be provided for each corresponding heating liquid discharge nozzle 73A. With this configuration, a feed flow rate of the heating liquid L4 can be set for the heating liquid discharge nozzles 73A individually. Furthermore, the supply source 76A may be provided for each corresponding heating liquid discharge nozzle 73A. With this configuration, a material of the heating liquid L4 can be set for the heating liquid discharge nozzles 73A individually.

The heating position mover 80A moves the heating position P in the moving direction of the boundary portion 8 while overlapping the heating position P with the boundary portion 8. For example, the heating position mover 80A moves the heating position P from the inner side of the substrate 2 toward the outer side of the substrate 2 in the diametrical direction thereof. In case that the rotation driver 20 (see FIG. 1) rotates the substrate holder 10, the boundary portion 8 can be moved from the inner side of the substrate 2 toward the outer side of the substrate 2 in the diametrical direction thereof so as not to be against the centrifugal force.

The heating position mover 80A is equipped with a switching mechanism 81A. The switching mechanism 81A moves the heating position P by switching each of the heaters 72A between an operating state and a stopped state. The heater 72A heats the substrate 2 locally in the operating state and stops the heating in the stopped state.

According to the present exemplary embodiment, the heater 72A need not be moved to move the heating position P. Therefore, connection of a pipeline to the heater 72A (for example, the heating liquid discharge nozzle 73A) is easily performed. The multiple number of heaters 72A are disposed and fixed in the clearance space 13 formed between the substrate 2 and the plate 11.

The switching mechanism 81A is composed of, by way of example, a multiple number of opening/closing valves 74A. These opening/closing valves 74A are controlled independently. The heater 72A connected to the corresponding opening/closing valve 74A in an open state discharges the heating liquid L4. Meanwhile, the heater 72A connected to the corresponding opening/closing valve 74A in a closed state does not discharge the heating liquid L4.

Furthermore, the switching mechanism 81A may have, instead of the opening/closing valve 74A, a directional control valve such as a three-way or four-way valve. The directional control valve switches a direction in which the heating liquid L4 flows. The directional control valve is capable of closing the flow path of the heating liquid L4. By using this directional control valve, the number of the valve to be provided may be reduced.

The heating controller 98 (see FIG. 2) moves the heating position P in the moving direction of the boundary portion 8 while overlapping the heating position P with the boundary portion 8 when viewed from the vertical direction. By way of example, the heating controller 98 may move the heating position P in the moving direction of the boundary portion 8 by operating the multiple number of heaters 72A, which are arranged in the diametrical direction of the substrate 2, in sequence. As a result, regardless of where the boundary portion 8 reaches, the boundary portion 8 can be heated intensively. The exposed portion 6 and the covered portion 7 are hardly heated by the heating liquid L4. Thus, the same effects as those of the first to third exemplary embodiments are obtained.

The heating controller 98 may operate the multiple number of heaters 72A in sequence while prohibiting the heaters 72A to be operated at the same time. The heating controller 98 may set one heater 72A to be in an operating state while setting the other heaters 72A to be in the stopped state. With this configuration, the boundary portion 8 can be heated more intensively.

The heating controller 98 may perform a control of keeping constant a total heating amount per unit area (unit: J/mm²) on the heating surface (for example, the bottom surface 2b of the substrate 2) in a period during which the heating position P is moved from the inner side of the substrate 2 toward the outer side of the substrate 2 in the diametrical direction thereof. As a specific example of this control, the above-described controls of (A) to (C) may be performed. The controls of (A) to (C) may be performed individually or in multiple combinations.

In the control of (A), whenever switching the heater 72A in the operating state from one at the inner side of the substrate 2 to one at the outer side in the diametrical direction of the substrate 2, the heating controller 98 may lengthen an interval of the switching. That is, the heating controller 98 may operate the heater 72A at the outer side in the diametrical direction of the substrate 2 for a longer time than the heater 72A at the inner side in the diametrical direction of the substrate 2.

Furthermore, in the present exemplary embodiment, while the liquid controller 96 stops the supply of the drying liquid L3 onto the substrate 2 and the heating controller 98 supplies the heating liquid L4 onto the edge portion of the substrate 2, the gas controller 97 may form the flow of the gas G2 above the edge portion of the substrate 2, the same as in the first exemplary embodiment.

Alternatively, as in the above-described second exemplary embodiment, the heating controller 98 may stop the supply of the heating liquid L4 and the rotation controller 95 may increase the rotation number of the substrate holder 10 at the same time as the liquid controller 96 stops the supply of the drying liquid L3.

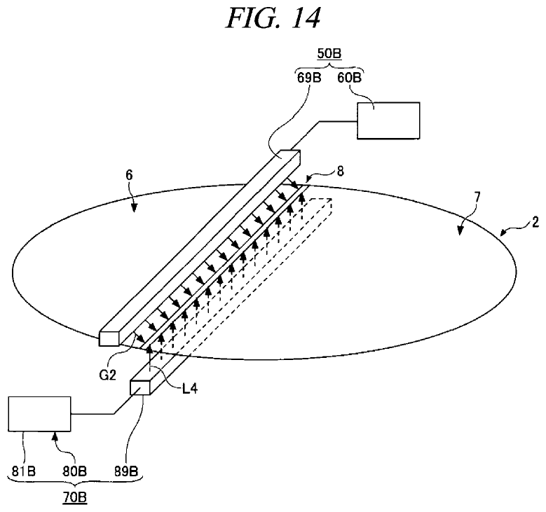

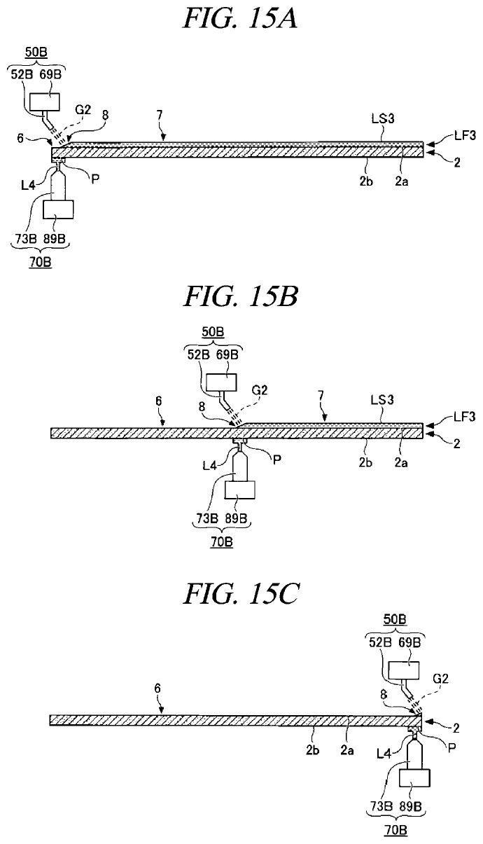

FIG. 14 is a perspective view illustrating a part of a substrate processing according to a fifth exemplary embodiment, which corresponds to FIG. 15B. FIG. 15A to FIG. 15C are side views illustrating parts of the substrate processing according to the fifth exemplary embodiment. FIG. 15A is a diagram illustrating a state where the exposed portion is formed at one end of the liquid film of the drying liquid according to the fifth exemplary embodiment. FIG. 15B is a diagram illustrating a state during the enlargement of the exposed portion according to the fifth exemplary embodiment. FIG. 15C is a diagram illustrating shortly before the enlargement of the exposed portion is completed according to the fifth exemplary embodiment. Hereinafter, the fifth exemplary embodiment will be described, focusing on distinctive features from the first to fourth exemplary embodiments.

In the process S105 (see FIG. 3) of forming the exposed portion 6 of the irregularity pattern 4 and in the process S106 (see FIG. 3) of enlarging the exposed portion 6, the substrate 2 is not rotated but stopped. Accordingly, the centrifugal force cannot be used to press the boundary portion 8. Thus, the pressure of the gas G2 from the gas supply unit 50B is used to press the boundary portion 8.

Although the gas supply unit 50B may have the vertical nozzle as the gas discharge nozzle configured to discharge the gas, the gas supply unit 50B is equipped with multiple inclined nozzles 52B in the present exemplary embodiment. The inclined nozzles 52B discharge the gas G2 in an inclined manner with respect to the vertical direction. Since the gas G2 has a horizontal component as well as a vertical component, the boundary portion 8 can be pressed efficiently.

The gas supply unit 50B has a straight line-shaped bar 69B which is disposed horizontally. The plurality of inclined nozzles 52B are fixed to this bar 69B and arranged in a lengthwise direction of the bar 69B. The inclined nozzles 52B concurrently discharge the gas G2 having a horizontal component acting in the same direction (for example, to the right in FIG. 15A to FIG. 15C) as the moving direction of the boundary portion 8. The flow of the gas G2 formed by the inclined nozzles 52B at the same time is formed in a range equal to or larger than the diameter of the substrate 2.

The gas supply unit 50B is equipped with a gas discharge nozzle moving mechanism 60B. The gas discharge nozzle moving mechanism 60B moves the bar 69B in a widthwise direction orthogonal to the lengthwise direction of the bar 69B, and moves the inclined nozzles 52B in the moving direction of the boundary portion 8. During the movement of the boundary portion 8, the boundary portion 8 can be pressed by the pressure of the gas G2.

The heating unit 70B is a heater configured to locally heat the liquid film LF3 of the drying liquid L3 and is equipped with multiple heating liquid discharge nozzles 73B. Further, the heating unit 70B has a straight line-shaped bar 89B which is disposed horizontally. The bar 89B of the heating unit 70B and the bar 69B of the gas supply unit 50B are arranged in parallel. The heating liquid discharge nozzles 73B are fixed to the bar 89B of the heating unit 70B. The heating liquid discharge nozzles 73B are arranged in a lengthwise direction of the bar 89B. Multiple heating positions P heated by the heating liquid discharge nozzles 73B at the same time are formed in a range equal to or larger than the diameter of the substrate 2.

The heating unit 70B is equipped with a heating position mover 80B configured to move the heating positions P. The heating position mover 80B is equipped with a heater moving mechanism 81B configured to move the bar 89B in a widthwise direction orthogonal to the lengthwise direction thereof and configured to move the heating liquid discharge nozzles 73B in the moving direction of the boundary portion 8. The multiple heating positions P heated by the heating liquid discharge nozzles 73B at the same time are formed continuously to cross the substrate 2 and moved to be overlapped with the boundary portion 8 when viewed from the vertical direction.

In the process S105 (see FIG. 3) of forming the exposed portion 6 of the irregularity pattern 4, the heating controller 98 (see FIG. 2) supplies the heating liquid L4 to one end of the substrate 2, and the gas supply unit 50B jets the gas G2 to the one end of the substrate 2 (see FIG. 15A). As a result, the exposed portion 6 is formed at the one end of the substrate 2.

In the process S106 (see FIG. 3) of enlarging the exposed portion 6, the heating controller 98 moves the heating liquid discharge nozzles 73B by moving the bar 89B, and the gas controller 97 (see FIG. 2) moves the inclined nozzles 52B by moving the bar 69B (see FIG. 15B and FIG. 15C).

The heating controller 98 moves the heating liquid discharge nozzles 73B in the moving direction of the boundary portion 8 while overlapping the heating positions P with the boundary portion 8 when viewed from the vertical direction. Further, the gas controller 97 moves the inclined nozzles 52B in the moving direction of the boundary portion 8 while pressing the boundary portion 8 by the gas G2.

In addition, although the heating position mover 80B according to the present exemplary embodiment is equipped with the heating position moving mechanism 81B, the heating position mover 80B may have a switching mechanism instead, the same as in the above-described third exemplary embodiment. The switching mechanism moves the heating positions P in the moving direction of the boundary portion 8 by allowing each of the heating liquid discharge nozzles 73B, which are arranged in the moving direction of the boundary portion 8, to be switched between the operating state and the stopped state. In this case, the heating liquid discharge nozzles 73B are arranged not only in the moving direction of the boundary portion 8 but also in a direction orthogonal to the moving direction of the boundary portion 8 to heat the entire substrate 2.

So far, the exemplary embodiments of the substrate processing apparatus and the substrate processing method are described. However, it should be noted that the present disclosure is not limited thereto. Within the scope of the claims, various changes, modifications, additions, deletions and combinations may be made, which are all regarded to be included in the inventive scope of the present disclosure.

The heater of the present disclosure is not limited to the example shown in the above-described exemplary embodiments. By way of example, the heater may be a heating gas discharge nozzle, a halogen heater, a heating LED, a laser heating head, an electric resistance heater, or the like. The heating gas discharge nozzle heats the substrate 2 by jetting a heating gas having a temperature higher than the room temperature to the substrate 2. A nitrogen gas, a dry air or the like may be used as the heating gas. The halogen heater heats the substrate 2 by irradiating light of a halogen lamp to the substrate 2. The heating LED heats the substrate 2 by irradiating a heat ray such as an infrared ray to the substrate 2. The laser heating head heats the substrate 2 by irradiating a laser beam to the substrate 2. The electric resistance heater generates heat to heat the substrate 2 when an electric current is supplied thereto.

Further, in case that the heating gas discharge nozzle, the halogen heater, the heating LED, the laser heating head or the electric resistance heater is used as the heater, this heater may be disposed under the substrate 2 held by the substrate holder 10 or may be disposed above the substrate 2. In the latter case, the heating surface heated by the heater is the liquid surface LS3 of the liquid film LF3. The heater may be disposed both under and above the substrate.

Moreover, in case that the heating gas discharge nozzle, the halogen heater, the heating LED, the laser heating head or the electric resistance heater is used as the heater, this heater may heat the liquid film LF3 by heating the substrate 2 or may heat the liquid film LF3 directly. If the liquid film LF3 is heated by heating the substrate 2, the following advantage can be obtained. That is, since the substrate 2 does not have fluidity unlike the drying liquid L3, the heated portion of the substrate 2 is not dispersed by the centrifugal force during the rotation of the substrate 2. Thus, it is possible to locally heat a preset position of the substrate 2 in the diametrical direction.

In the above-described exemplary embodiments, the present disclosure is applied to the drying of the liquid film LF3 of the drying liquid L3. However, the present disclosure may be applied to the drying of the liquid film LF2 of the rinse liquid L2. In such a case, the exposed portion is formed on the liquid film LF2 of the rinse liquid L2, and this exposed portion is enlarged. In case of ending the cleaning of the substrate without replacing the liquid film LF2 of the rinse liquid L2 with the liquid film LF3 of the drying liquid L3, the present disclosure may be applied to the drying of the liquid film LF2 of the rinse liquid L2.

According to the exemplary embodiment, it is possible to suppress the pattern collapse of the irregularity pattern when drying the liquid film covering the irregularity pattern.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a substrate holder configured to hold a substrate such that a surface of the substrate on which an irregularity pattern is formed faces upwards;
a liquid supply unit configured to supply a processing liquid onto the substrate, which is held by the substrate holder, from above the substrate to thereby form a liquid film which covers a recess of the irregularity pattern;
a heating unit comprising a heater configured to locally heat the liquid film and a heating position mover configured to move a heating position heated by the heater; and
a heating controller configured to control the heating unit,
wherein, while overlapping the heating position with a boundary portion when viewed from a vertical direction, the boundary portion being provided between an exposed portion where the recess is entirely exposed from the processing liquid in a depth direction thereof and a covered portion where the recess is entirely filled with the processing liquid in the depth direction thereof, the heating controller moves the heating position in a moving direction of the boundary portion as a direction in which the exposed portion is enlarged.

2. The substrate processing apparatus of claim 1, further comprising:
a rotation driver configured to rotate the substrate holder; and
a rotation controller configured to control the rotation driver,
wherein the heating controller moves the heating position from an inner side of the substrate toward an outer side of the substrate in a diametrical direction thereof while the rotation controller is rotating the substrate along with the substrate holder.

3. The substrate processing apparatus of claim 2,
wherein the heating controller controls a total heating amount per unit area on a heating surface heated by the heater to be maintained constant in a period during which the heating position is moved from the inner side of the substrate toward the outer side of the substrate in the diametrical direction thereof.

4. The substrate processing apparatus of claim 3,
wherein the heating controller slows down a moving speed of the heating position as the heating position is moved from the inner side of the substrate toward the outer side of the substrate in the diametrical direction thereof.

5. The substrate processing apparatus of claim 4,
wherein the rotation controller reduces a rotation number of the substrate holder as the heating controller moves the heating position from the inner side of the substrate toward the outer side of the substrate in the diametrical direction thereof.

6. The substrate processing apparatus of claim 4,
wherein the heating controller increases a heating amount per unit time as the heating position is moved from the inner side of the substrate toward the outer side of the substrate in the diametrical direction thereof.

7. The substrate processing apparatus of claim 3,
wherein the rotation controller reduces a rotation number of the substrate holder as the heating controller moves the heating position from the inner side of the substrate toward the outer side of the substrate in the diametrical direction thereof.

8. The substrate processing apparatus of claim 3,
wherein the heating controller increases a heating amount per unit time as the heating position is moved from the inner side of the substrate toward the outer side of the substrate in the diametrical direction thereof.

9. The substrate processing apparatus of claim 3, further comprising:
a liquid controller configured to control the liquid supply unit,
wherein the liquid supply unit comprises a liquid discharge nozzle configured to discharge the processing liquid and a liquid discharge nozzle moving mechanism configured to move the liquid discharge nozzle from the inner side of the substrate toward the outer side of the substrate in the diametrical direction thereof, and
the liquid controller discharges the processing liquid from the liquid discharge nozzle and, concurrently, moves the liquid discharge nozzle in the moving direction of the boundary portion while placing a discharge opening of the liquid discharge nozzle at a position outer than the boundary portion in the diametrical direction of the substrate.

10. The substrate processing apparatus of claim 2, further comprising:
a liquid controller configured to control the liquid supply unit,
wherein the liquid supply unit comprises a liquid discharge nozzle configured to discharge the processing liquid and a liquid discharge nozzle moving mechanism configured to move the liquid discharge nozzle from the inner side of the substrate toward the outer side of the substrate in the diametrical direction thereof, and
the liquid controller discharges the processing liquid from the liquid discharge nozzle and, concurrently, moves the liquid discharge nozzle in the moving direction of the boundary portion while placing a discharge opening of the liquid discharge nozzle at a position outer than the boundary portion in the diametrical direction of the substrate.

11. The substrate processing apparatus of claim 2, further comprising:
a liquid controller configured to control the liquid supply unit,
wherein the liquid supply unit comprises a liquid discharge nozzle configured to discharge the processing liquid of a room temperature onto the substrate, and
the liquid controller stops the discharge of the processing liquid of the room temperature from the liquid discharge nozzle while the heating controller moves the heating position.

12. The substrate processing apparatus of claim 2,
wherein the heating position mover comprises a heating position moving mechanism configured to move the heater to move the heating position in the moving direction of the boundary portion.

13. The substrate processing apparatus of claim 2,
wherein the heater includes multiple heaters, and the multiple heaters are arranged in the moving direction of the boundary portion, and
the heating position mover comprises a switching mechanism configured to move the heating position in the moving direction of the boundary portion by switching each of the heaters, which are arranged in the moving direction of the boundary portion, between an operating state and a stopped state.

14. The substrate processing apparatus of claim 1, further comprising:
a liquid controller configured to control the liquid supply unit,
wherein the liquid supply unit comprises a liquid discharge nozzle configured to discharge the processing liquid and a liquid discharge nozzle moving mechanism configured to move the liquid discharge nozzle from an inner side of the substrate toward an outer side of the substrate in a diametrical direction thereof, and
the liquid controller discharges the processing liquid from the liquid discharge nozzle and, concurrently, moves the liquid discharge nozzle in the moving direction of the boundary portion while placing a discharge opening of the liquid discharge nozzle at a position outer than the boundary portion in the diametrical direction of the substrate.

15. The substrate processing apparatus of claim 1, further comprising:
a liquid controller configured to control the liquid supply unit,
wherein the liquid supply unit comprises a liquid discharge nozzle configured to discharge the processing liquid of a room temperature onto the substrate, and
the liquid controller stops the discharge of the processing liquid of the room temperature from the liquid discharge nozzle while the heating controller moves the heating position.

16. The substrate processing apparatus of claim 1,
wherein the heating position mover comprises a heating position moving mechanism configured to move the heater to move the heating position in the moving direction of the boundary portion.

17. The substrate processing apparatus of claim 1,
wherein the heater includes multiple heaters, and the multiple heaters are arranged in the moving direction of the boundary portion, and
the heating position mover comprises a switching mechanism configured to move the heating position in the moving direction of the boundary portion by switching each of the heaters, which are arranged in the moving direction of the boundary portion, between an operating state and a stopped state.

18. The substrate processing apparatus of claim 1,
wherein the heater comprises a heating liquid discharge nozzle configured to discharge a heating liquid configured to heat the substrate onto the substrate, which is held by the substrate holder, from below the substrate.

19. The substrate processing apparatus of claim 1, further comprising:
a gas supply unit configured to supply a gas onto the substrate, which is held by the substrate holder, from above the substrate;
a gas controller configured to control the gas supply unit; and
a liquid controller configured to control the liquid supply unit,
wherein the gas supply unit comprises an inclined nozzle configured to form, above the substrate, a flow of the gas flowing from an inner side of the substrate toward an outer side of the substrate in a diametrical direction thereof as the gas flows downwards, and
the gas controller forms the flow of the gas above an edge portion of the substrate while the liquid controller stops supply of the processing liquid and the heating controller supplies the heating liquid onto the edge portion of the substrate.

20. A substrate processing method, comprising:
forming, by holding a substrate such that a surface of the substrate on which an irregularity pattern is formed faces upwards and by supplying a processing liquid onto the substrate from above the substrate, a liquid film which covers a recess of the irregularity pattern;
forming an exposed portion where the recess is entirely exposed from the processing liquid in a depth direction thereof, a covered portion where the recess is entirely filled with the processing liquid in the depth direction thereof and a boundary portion between the exposed portion and the covered portion; and
enlarging the exposed portion by moving the boundary portion,
wherein the enlarging of the exposed portion comprises:
locally heating the liquid film by a heater; and
moving a heating position on the liquid film heated by the heater in a moving direction of the boundary portion while overlapping the heating position with the boundary portion when viewed from a vertical direction.
